(19) United States
(12) Patent Application Publication
(10) Pub. No.: US 2026/0004016 A1
(43) Pub. Date: Jan. 1, 2026

(54) AUTO-GENERATION OF PIPING AND INSTRUMENTATION DIAGRAMS

(71) Applicant: Chevron U.S.A. Inc., San Ramon, CA (US)

(72) Inventors: Rajesh Navnitbhai Patel, Missouri City, TX (US); Subbiah Muthiah, Katy, TX (US); Ashok Sanjoy Hati, Katy, TX (US)

(21) Appl. No.: 19/215,857

(22) Filed: May 22, 2025

Related U.S. Application Data
(60) Provisional application No. 63/665,114, filed on Jun. 27, 2024.

(51) Int. Cl. G06F 30/18

(52) U.S. Cl. CPC G06F 30/18

(57) ABSTRACT

A computer-implemented method for generating a piping and instrumentation diagram (P&ID) for a corporate entity may include presenting an initial page on a web based application. The method may also include obtaining, by the web based application, an input on the page. The method may further include validating, by the web based application, the input. The method may also include generating, by the web based application, the P&ID using the input after validating the input.

### CROSS-REFERENCE TO RELATED APPLICATIONS

This application claims priority to U.S. Provisional Patent Application Ser. No. 63/665,114 titled “Auto-Generation Of Piping And Instrumentation Diagrams” and filed on Jun. 27, 2024, the entire contents of which are hereby incorporated herein by reference.

### TECHNICAL FIELD

The present application is related to piping and instrumentation diagrams (P&IDs) and, more particularly, to systems and methods for a web-based application for the automated design, management, and maintenance of smart P&IDs (and also to other engineering drawings such as Process Flow Diagrams (PFDs), Block Flow Diagrams (BFDs), and Single Line Diagrams (SLDs)).

### BACKGROUND

The design of systems for piping and instrumentation involves a significant amount of input from one or more users (e.g., engineers, management). For example, engineering drawing development involves providing a sketch or marked up copy of the drawing(s) to a draftsman who manually creates the drawing (e.g., in a CAD package). This is a manual, time-intensive and error-prone method. Also, such as with larger corporate portfolios, different users may be involved in the different projects. Also, projects in different geographic regions may result in differences in what would otherwise be similar projects. As such, current practice for engineering design is not standardized and can result in different designs for similar applications. As a result, inconsistencies and a lack of standardization may result across projects. Some consequences of this may be increased installation costs, increased maintenance costs, and excess time spent in designing and implementing the various projects.

### SUMMARY

In general, in one aspect, the disclosure relates to a computer-implemented method for generating a piping and instrumentation diagram (P&ID) for a corporate entity. The computer-implemented method may include presenting an initial page on a web based application. The computer-implemented method may also include obtaining, by the web based application, an input on the page. The computer-implemented method may further include validating, by the web based application, the input. The computer-implemented method may also include generating, by the web based application, the P&ID using the input after validating the input.

These and other aspects, objects, features, and embodiments will be apparent from the following description and the appended claims.

### BRIEF DESCRIPTION OF THE DRAWINGS

The drawings illustrate only example embodiments and are therefore not to be considered limiting in scope, as the example embodiments may admit to other equally effective embodiments. The elements and features shown in the drawings are not necessarily to scale, emphasis instead being placed upon clearly illustrating the principles of the example embodiments. Additionally, certain dimensions or positions may be exaggerated to help visually convey such principles. In the drawings, the same reference numerals used in different figures may designate like or corresponding but not necessarily identical elements.

FIG. 1 shows a flowchart of a method for auto-generating a P&ID system according to certain example embodiments.

FIG. 2 shows a diagram depicting the overall strategy for templates using the web based application according to certain example embodiments.

FIG. 3 shows a diagram depicting the overall strategy for projects using the web based application according to certain example embodiments.

FIGS. 4 through 38 show examples of screenshots of pages that may be presented during interaction with the web based application according to certain example embodiments.

FIG. 39 shows an overall process flow diagram involving a P&ID system according to certain example embodiments.

FIGS. 40A through 40F show a P&ID workflow according to certain example embodiments.

FIG. 41 shows an architecture diagram of a P&ID system according to certain example embodiments.

### DESCRIPTION OF THE INVENTION

The present disclosure is related to:

Developing engineering design logic and templates for minimum functional objective (MFO) based piping and instrumentation diagram (P&ID) at both system and equipment levels; and

Designing systems and methods for a web-based application for auto-generating, management, and maintenance of smart P&IDs (e.g., in SmartPlant P&ID (SPID) environment (SmartPlant is a registered trademark of Hexagon Technology Center GMBH, Switzerland.)).

The disclosed system design logic and digital web application allows smart P&IDs to be auto-generated repeatably by a design/project engineer at his/her desktop. The disclosed systems and methods facilitate standardization and enable consistent and rapid generation of smart engineering design/drawings at designer's desktop. It also allows the designer to select/deselect different options to generate corresponding smart drawings swiftly and repeatably. An example process of engineering drawings generation for a project may include the following steps:
1. Develop step by step engineering design logic for an engineering system with corresponding templates (e.g., a library of MFO based engineering designs at system and equipment level).
2. Develop template library for a smart P&ID application (e.g., SPID).
3. Through a web-based application, allowing an administrator to import the design logic and create a project.
4. Based on user selections and association of design logic, templates and features, using the web-based application to generate smart drawings and make them available on desktop to view/download/print.
5. Storing the smart drawings are in a native format in which they can be edited for any modifications and detailed designs for the project.

The design of P&IDs can involve a significant amount of input from subject matter experts from various engineering disciplines (including Process, Instrumentation & Control, Mechanical, Electrical, Design Assurance, Fire & Safety, Operations, HES). Auto-generation system design involves guiding a team of digital/IT subject matter experts (including system architects, business analysts, full-stack developers, interface developers for third-party software package). It may also be desirable to engage Information Management personnel for document control and managing a repository (library) of design documents/templates under version control.

The disclosed method translates engineering process system design logic and templates, accepts project user inputs, and auto-generates smart P&IDs using a web-based application. This eliminates the need to cycle through a manual mark-up and drafting work process and enables project engineers to design/modify process systems and auto-generate smart drawings at their desktop.

The example embodiments discussed herein are directed to systems and methods for a web-based application for the automated design, management, and maintenance of P&IDs. The example embodiments discussed herein may also be directed to systems and methods for developing design logic and templates for an MFO based equipment or system design. Example embodiments can be used to auto-generate smart P&IDs (equipment and/or system level P&IDs), process flow diagrams, electrical/instrumentation drawings, block flow diagrams, material selection diagrams, etc., in one or more of any of a number of industries. Examples of industries for which example embodiments can be used can include, but are not limited to, oil and gas (e.g., exploration, production, refining), chemical production and/or manufacturing, and electric power.

Example embodiments can be used so that a single user, a team of users, and/or users from multiple corporate disciplines may auto-generate P&IDs. Example embodiments described herein can be designed to comply with certain standards and/or requirements. Examples of entities that set such standards and/or requirements can include, but are not limited to, the Environmental Protection Agency (EPA), the American Petroleum Institute (API), the World Resources Institute (WRI), the European Union (EU), the Center For Resource Solutions (CRS), the Intergovernmental Panel on Climate Change (IPCC), the American Society of Mechanical Engineers (ASME), the International Electrotechnical Commission (IEC), the Institute of Electrical and Electronics Engineers (IEEE), and the International Organization for Standardization (ISO). The use of the terms “about”, “approximately”, and similar terms applies to all numeric values, whether or not explicitly indicated. These terms generally refer to a range of numbers that one of ordinary skill in the art would consider as a reasonable amount of deviation to the recited numeric values (i.e., having the equivalent function or result). For example, this term may be construed as including a deviation of ±10 percent of the given numeric value provided such a deviation does not alter the end function or result of the value. Therefore, a value of about 1% may be construed to be a range from 0.9% to 1.1%. Furthermore, a range may be construed to include the start and the end of the range. For example, a range of 10% to 20% (i.e., range of 10%-20%) includes 10% and also includes 20%, and includes percentages in between 10% and 20%, unless explicitly stated otherwise herein. Similarly, a range of between 10% and 20% (i.e., range between 10%-20%) includes 10% and also includes 20%, and includes percentages in between 10% and 20%, unless explicitly stated otherwise herein.

It is understood that when combinations, subsets, groups, etc. of elements are disclosed (e.g., combinations of components in a composition, or combinations of steps in a method), that while specific reference of each of the various individual and collective combinations and permutations of these elements may not be explicitly disclosed, each is specifically contemplated and described herein. By way of example, if an item is described herein as including a component of type A, a component of type B, a component of type C, or any combination thereof, it is understood that this phrase describes all of the various individual and collective combinations and permutations of these components. For example, in some embodiments, the item described by this phrase could include only a component of type A. In some embodiments, the item described by this phrase could include only a component of type B. In some embodiments, the item described by this phrase could include only a component of type C. In some embodiments, the item described by this phrase could include a component of type A and a component of type B. In some embodiments, the item described by this phrase could include a component of type A and a component of type C. In some embodiments, the item described by this phrase could include a component of type B and a component of type C. In some embodiments, the item described by this phrase could include a component of type A, a component of type B, and a component of type C. In some embodiments, the item described by this phrase could include two or more components of type A (e.g., A1 and A2). In some embodiments, the item described by this phrase could include two or more components of type B (e.g., B1 and B2). In some embodiments, the item described by this phrase could include two or more components of type C (e.g., C1 and C2). In some embodiments, the item described by this phrase could include two or more of a first component (e.g., two or more components of type A (A1 and A2)), optionally one or more of a second component (e.g., optionally one or more components of type B), and optionally one or more of a third component (e.g., optionally one or more components of type C). In some embodiments, the item described by this phrase could include two or more of a first component (e.g., two or more components of type B (B1 and B2)), optionally one or more of a second component (e.g., optionally one or more components of type A), and optionally one or more of a third component (e.g., optionally one or more components of type C). In some embodiments, the item described by this phrase could include two or more of a first component (e.g., two or more components of type C (C1 and C2)), optionally one or more of a second component (e.g., optionally one or more components of type A), and optionally one or more of a third component (e.g., optionally one or more components of type B).

If a component of a figure is described but not expressly shown or labeled in that figure, the label used for a corresponding component in another figure can be inferred to that component. Conversely, if a component in a figure is labeled but is not described, the description for such component can be substantially the same as the description for the corresponding component in another figure. The numbering scheme for the various components in the figures herein is such that each component is a three-digit number or a four-digit number, and corresponding components in other figures have the identical last two digits. For any figure shown and described herein, one or more of the components may be omitted, added, repeated, and/or substituted. Accordingly, embodiments shown in a particular figure should not be considered limited to the specific arrangements of components shown in such figure.

Further, a statement that a particular embodiment (e.g., as shown in a figure herein) does not have a particular feature or component does not mean, unless expressly stated, that such embodiment is not capable of having such feature or component. For example, for purposes of present or future claims herein, a feature or component that is described as not being included in an example embodiment shown in one or more particular drawings is capable of being included in one or more claims that correspond to such one or more particular drawings herein.

Example embodiments of auto-generating P&IDs will be described more fully hereinafter with reference to the accompanying drawings, in which example embodiments of auto-generating P&IDs are shown. Auto-generating P&IDs may, however, be embodied in many different forms and should not be construed as limited to the example embodiments set forth herein. Rather, these example embodiments are provided so that this disclosure will be thorough and complete, and will fully convey the scope of auto-generating P&IDs to those of ordinary skill in the art. Like, but not necessarily the same, elements (also sometimes called components) in the various figures are denoted by like reference numerals for consistency.

Terms such as “first”, “second”, “above”, “below”, “inner”, “outer”, “distal”, “proximal”, “end”, “top”, “bottom”, “upper”, “lower”, “side”, “left”, “right”, “front”, “rear”, and “within”, when present, are used merely to distinguish one component (or part of a component or state of a component) from another. This list of terms is not exclusive. Such terms are not meant to denote a preference or a particular orientation unless explicitly stated, and they are not meant to limit embodiments of auto-generating P&IDs. In the following detailed description of the example embodiments, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

A system for auto-generating P&IDs according to certain example embodiments may include multiple components. For example, a system may include an auto generation P&ID system, a network manager, one or more sensor devices, one or more users (including one or more associated user systems), and one or more suppliers (including one or more associated supplier systems). The auto generation P&ID system in this example may include a web based application, which includes a controller. The system may also include a number of communication links to facilitate communication between various components within the system.

A system may include any number (e.g., one, two, five, twenty, one hundred, three thousand) of users. A user can be any person, group, or entity in involved in developing, implementing, modifying, regulating, maintaining, installing, testing, using, and/or otherwise associated with a P&ID. Examples of a user can include, but are not limited to, a business owner, an employee or other representative of a company, a supplier, a research scientist, an analyst, a compliance manager, an engineer, a company representative, an inspector, a consultant, a government representative, a regulator, a contractor, and a manufacturer's representative.

A user may be associated with any geographic location(s), industry served, and/or type of facility in which the P&ID system is installed. A user can be a corporate entity that has multiple business segments. A user can be represented by one or more individuals (e.g., employees, officers) and/or other entities (e.g., an accounting firm, an auditing firm) when using the example web based application.

A user can use one or more user systems, which may include a display (e.g., a GUI). A user system of a user can interact with (e.g., send data to, obtain data from) the auto generation P&ID system (or portions thereof, such as the web based application and/or the controller thereof) and/or one or more suppliers of the user via an application interface and using one or more communication links. Examples of a user system can include, but are not limited to, a cell phone, a laptop computer, a desktop computer, an electronic tablet, and a specialized handheld device.

The system can include any number (e.g., one, two, five, twenty, one hundred, three thousand) of suppliers. A supplier can be any person, group, or entity in involved in developing, implementing, modifying, regulating, maintaining, installing, testing, using, and/or otherwise associated with a P&ID. A supplier can provide information, goods, and/or services related to a P&ID generated by the web based application. The information, goods, and/or services provided by a supplier may include, but are not limited to, regulatory information, standards, statutes, nameplate information, manufacturing specifications, historical data, test data, schedules (e.g., manufacturing, delivery, maintenance), maintenance reports, costs, environmental data, weather information, work experience, and fees.

A supplier can use and/or include one or more supplier systems, which may include a display (e.g., a GUI). A supplier system of a supplier can interact with (e.g., send data to, obtain data from) the auto generation P&ID system (or portion thereof, such as the controller of the web based application) via an application interface and using one or more communication links. Examples of a supplier system can include, but are not limited to, a cell phone, a laptop computer, a desktop computer, a server, an electronic tablet, and a specialized handheld device.

Each sensor device of the system includes one or more sensors that measure one or more parameters (e.g., pressure, flow rate, temperature, opacity, heat rate, humidity, fluid content, voltage, current, chemical elements in a soil sample). Examples of a sensor of a sensor device can include, but are not limited to, a temperature sensor, a flow sensor, a pressure sensor, a proximity sensor, a gas spectrometer, a voltmeter, an ammeter, and a camera. A sensor device can be integrated with or measure a parameter associated with a location in which a P&I system is installed or is planned based on a P&IDs. For example, a sensor device can be integrated with or connected to a valve of an existing P&I system based on P&IDs. As another example, a sensor device can measure environmental data (e.g., temperature, humidity) at a site where a P&I system is planned using P&IDs. In some cases, a number of sensor devices, each measuring one or more parameters, may be used in combination to determine and confirm whether a controller should take a particular action (e.g., recommend replacing a valve, operate a valve, schedule an installation or maintenance, operate or adjust the operation of a pump, send a notification).

The network manager of the system can be configured to control and/or communicate with the auto generation P&ID system (including the example web based application or controller thereof). For example, the network manager may be configured to provide updated instructions for the users. As another example, the network manager can facilitate communication between the web based application of the auto generation P&ID system and one or more other web based applications of one or more other auto generation P&ID systems outside the system.

The network manager may include a controller. As described herein, control and/or communication with the network manager may include communicating with the web based application in the same system and/or with one or more other web based applications of one or more other auto generation P&ID systems in one or more other systems. In such a case, the network manager may facilitate such control and/or communication. The network manager may be called by other names, including but not limited to a master controller, a network controller, and an enterprise manager.

In certain example embodiments, the auto generation P&ID system, including components (e.g., the web based application, the controller) thereof, may be configured to perform any of a number of functions associated with P&IDs. For example, the controller of the web based application of the auto generation P&ID system may be configured to present a series of pages on the web based application to a user, where each page presented by the web based application is based on one or more inputs provided by a user through a prior page presented by the web based application. Based on the inputs provided by a user through one or more of the pages, the web based application may generate one or more of any number of results, including but not limited to updating a profile for a user or group of users, updating a table, generating a set of P&IDs, ordering equipment, scheduling labor, assessing costs (e.g., fees, expenses), updating a set of P&IDs, making a recommendation, generating a notification, setting security requirements, and verifying information.

When a page is presented (e.g., on the display of a user system) to a user, the user may provide one or more inputs (e.g., selections, entries) on the page. In some cases, an input is a selection (e.g., a menu item, a radio button) among multiple selection options on the page. In other cases, an input may be an entry (e.g., free form text, uploading a file) made on the page. Each input provided by a user is used by the controller to determine which page to show next, which tables to draw from, which to employ, which regulations to apply, which recommendation to make, and/or perform other actions.

When an input is received by the controller of the web based application of the auto generation P&ID system, the controller may perform one or more of a number of checks or validations with respect to the input. For example, the controller may verify that the input falls within a set of guidelines that currently apply to the input. A guideline may be rule or set of rules that govern over a particular aspect (e.g., over data, over suppliers, over users) of the process used to generate a P&ID. A guideline may be set and/or modified by a user, by regulation, by industry standard, by default, and/or by some other entity or factor.

The controller of the web based application of the auto generation P&ID system may be configured to help establish, in real time and with a continual ability to be modified by a user, how P&IDs are generated using the inputs provided by the one or more users. One or more other components or portions of the web based application may be used to enact one or more of the inputs of various inputs.

The web based application may communicate directly with each of the users (including any associated user systems), each of the suppliers (including any associated supplier systems), the network manager, and/or each of the sensor devices. Such communication can occur using the communication links. Each communication link can include wired and/or wireless technology. A communication link can be used for the transmission of signals (e.g., communication signals, control signals, data) between the user systems, the network manager, the sensor devices, the supplier systems, and the web based application in the system.

The web based application may include a controller according to certain example embodiments. In such a case, the controller of the web based application may include multiple components. For example, the controller of the web based application may include a control engine, a data processing module, an organization module, a communication module, a timer, a power module, a storage repository (which may include, for example, protocols, algorithms, and stored data), a hardware processor, memory, a transceiver, an application interface, a security module, recommendation module, a guideline verification module, a page generation module, and an input processing module. The various components of the controller may be centrally located. In addition, or in the alternative, some of the components of the controller may be located remotely from (e.g., in the cloud, at an office building) one or more of the other components of the controller.

A computing device may implement one or more of the various techniques described herein. For example, a controller (including components thereof, such as a control engine, a hardware processor, a storage repository, a power module, and a transceiver) may be considered a computing device. The computing device may include one or more processors or processing units, one or more memory/storage components, one or more input/output (I/O) devices, and a bus that allows the various components and devices to communicate with one another.

Various techniques are described herein in the general context of software or program modules. Generally, software includes routines, programs, objects, components, data structures, and so forth that perform particular tasks or implement particular abstract data types. An implementation of these modules and techniques are stored on or transmitted across some form of computer readable media. Computer readable media is any available non-transitory medium or non-transitory media that is accessible by a computing device. By way of example, and not limitation, computer readable media includes “computer storage media”.

“Computer storage media” and “computer readable medium” include volatile and non-volatile, removable and non-removable media implemented in any method or technology for storage of information such as computer readable instructions, data structures, program modules, or other data. Computer storage media include, but are not limited to, computer recordable media such as RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which is used to store the desired information and which is accessible by a computer.

A computer device (also sometimes called a computer system) is connected to a network (e.g., a LAN, a WAN such as the Internet, cloud, or any other similar type of network) via a network interface connection according to some example embodiments. Those skilled in the art will appreciate that many different types of computer systems exist (e.g., desktop computer, a laptop computer, a personal media device, a mobile device, such as a cell phone or personal digital assistant, or any other computing system capable of executing computer readable instructions), and the aforementioned input and output means take other forms, now known or later developed, in other example embodiments. Generally speaking, the computer system includes at least the minimal processing, input, and/or output means necessary to practice one or more embodiments.

Further, those skilled in the art will appreciate that one or more elements of a computer device may be located at a remote location and connected to the other elements over a network in certain example embodiments. Further, one or more embodiments can be implemented on a distributed system having one or more nodes, where each portion of the implementation (e.g., a web based application) is located on a different node within the distributed system. In one or more embodiments, the node corresponds to a computer system. Alternatively, the node corresponds to a processor with associated physical memory in some example embodiments. The node alternatively corresponds to a processor with shared memory and/or resources in some example embodiments.

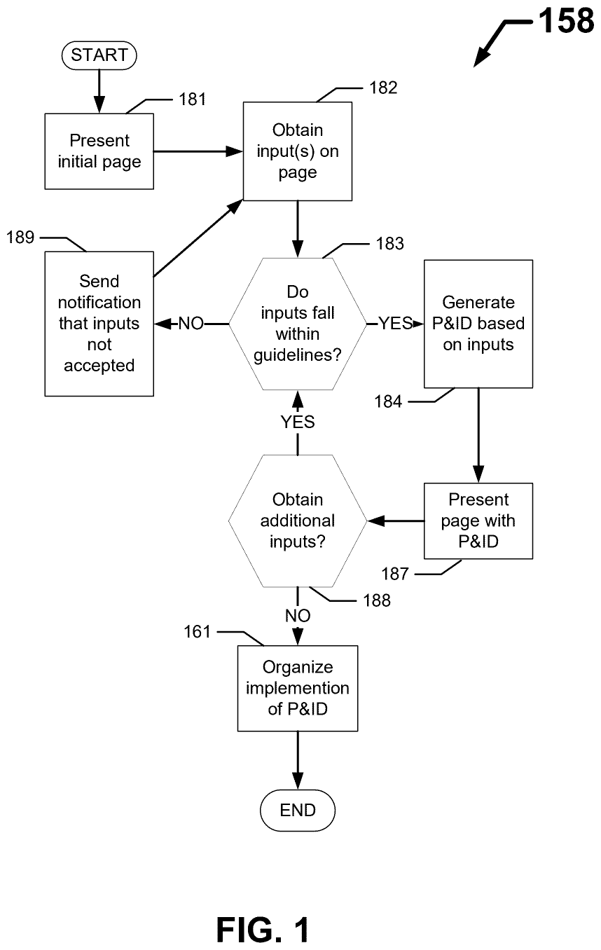

FIG. 1 shows a flowchart 158 of a method for auto-generating P&IDs using a web based application according to certain example embodiments. While the various steps in this flowchart 158 are presented sequentially, one of ordinary skill will appreciate that some or all of the steps may be executed in different orders, may be combined or omitted, and some or all of the steps may be executed in parallel. Further, in one or more of the example embodiments, one or more of the steps shown in this example method may be omitted, repeated, and/or performed in a different order.

In addition, a person of ordinary skill in the art will appreciate that additional steps not shown in FIG. 1 may be included in performing this method. Accordingly, the specific arrangement of steps should not be construed as limiting the scope. Further, a particular computing device, such as a computing device discussed above, may be used to perform or facilitate performance of one or more of the steps (or portions thereof) for the method shown in FIG. 1 in certain example embodiments. Any of the functions (or portions thereof) performed below by a controller may involve the use of one or more protocols, one or more algorithms, and/or stored data stored in a storage repository. In some cases, one or more of the various steps in the method of FIG. 1 can be performed automatically, as by the controller of the web based application.

The method shown in FIG. 1 is merely an example that may be performed by using an example system described herein. In other words, systems for generating P&IDs using a web based application may perform other functions using other methods in addition to and/or aside from those shown in FIG. 1. The method shown in the flowchart 158 of FIG. 1 begins at the START step and proceeds to step 181, where a page is presented. The initial page may be generated by the page generation module of the controller of the web based application. The initial page may be presented by the controller of the web based application. The initial page may be generated and presented to a user on a user system using one or more protocols, one or more algorithms, stored data, the communication module, and/or the application interface of the controller of the web based application. The initial page may be presented in any of a number of different formats using any of a number of different media. When the initial page is presented, it may be interactive (e.g., via a user interface) with a user.

In some cases, a particular user interacting with the initial page is identified. For example, the user may present login credentials to identify the user before the initial page is presented. As another example, the user may undergo a biometric scan to identify the user before the initial page is presented. In this way, the authority and permissions of the user, retrieved from stored data, may be used by the controller to tailor (e.g., in terms of format, by activating and/or deactivating certain fields) the initial page. Once the preliminary screening is performed, the initial page may be presented.

In step 182, one or more inputs on the initial page are obtained. As used herein, the term “obtaining” may include receiving, retrieving, accessing, generating, etc. or any other manner of obtaining an input and/or other information associated with generating a P&ID. An input may be obtained by a controller of the web based application of an auto generation P&ID system using a communication module and/or an application interface of the controller of the web based application.

In some cases, obtaining an input may be an iterative process, taking multiple steps (e.g., multiple iterations of the page, multiple back-and-forths within the same page) before the input is complete. Generally, when an input is obtained, an input processing module of the controller may be configured to perform one or more of a number of checks or validations (e.g., using one or more guidelines, using one or more protocols) with respect to the input. In this way, in real time, an input processing module may determine whether the input is valid and may be used. The input processing module may also be configured to determine whether the user providing the input is authorized to do so and/or how to resolve issues (e.g., using a hierarchy) that arise when the input conflicts with a prior input.

In step 183, a determination is made as to whether the inputs fall within guidelines. Put another way, the one or more inputs are validated. The determination as to whether the one or more inputs fall within guidelines may be made by a guideline verification module of the controller using a control engine 206, one or more protocols, one or more algorithms, and/or stored data. The guidelines being considered may apply specifically to the one or more inputs, the user, and/or any other factors related to each of the inputs being considered. For example, a guideline verification module may determine whether an input falls within a range of parameters (e.g., dates, business entity, user authority, hierarchical resolution of conflicts). If all of the inputs fall within guidelines, then the process proceeds to step 184. If all of the inputs fall outside one or more guidelines, then the process proceeds to step 189.

In step 184, one or more P&IDs are generated based on the inputs. In certain example embodiments, the P&IDs are generated using a control engine, a guideline verification module, one or more protocols, one or more algorithms, and/or stored data. Generating the P&IDs may be done in real time relative to obtaining the inputs.

In step 187, one or more of the P&IDs are presented. The P&IDs may be presented on a page by a page generation module of the controller of the web based application. The P&IDs may be presented to a user on a user system. The P&IDs may be presented to the same user as in step 181, the same user as in a prior version or iteration of the P&IDs, and/or some other user. The P&IDs may be for the first version of a new project, a revised version of a new project, or a revised version of an existing project.

A page generation module may generate and present the P&IDs using a control engine, one or more protocols, one or more algorithms, stored data, a communication module, and/or an application interface of the controller of the web based application. The P&IDs may be presented in any of a number of different formats using any of a number of different media. When the P&IDs are presented, they may be interactive (e.g., via a user interface) with a user.

In step 188, a determination is made as to whether another input on the page is obtained. As with step 182 above, each input may be obtained from one or more users via one or more user systems. An input may be obtained by a controller of the web based application of an auto generation P&ID system using a communication module and/or an application interface of the controller of the web based application. If one or more inputs are obtained, then the process reverts to step 183. If one or more inputs are not obtained, then the process proceeds to step 161.

In step 189, a notification that one or more of the inputs on a page are not acceptable is sent. Such a notification may take one or more of a number of forms. Examples of such forms of the notification may include, but are not limited to, an email, a text message, an audio output, an alarm, a message on a display, an alert on an app, and a light indication. Such a notification may be sent to the user providing the input at issue. In addition, or in the alternative such a notification may be sent to a third party (e.g., a supervisor, an authorized representative). More generally, if there is a failure, the controller shows the user what the failure is in real time. In such cases, the user may then take corrective action to overcome the failure in real time by providing a different input on the page. In certain example embodiments, the controller presents, in real time, one or more options to a user that, once selected by the user, allows the failure to be overcome.

Such a notification may be generated and sent by the controller of the web based application. In such a case, if an input does not fall within one or more guidelines, as determined by a guideline verification module, the guideline verification module may communicate the details to a control engine of the controller, which in turn may generate and send the notification to communicate the issue (e.g., in general terms, in specific terms) that the input cannot be accepted (either in full or in part).

The controller may use, for example, a control engine, an application interface, a communication module, one or more protocols, one or more algorithms, and/or stored data to generate and/or send the notification. In some cases, a notification may include one or more alternatives and/or solutions that the user may take to overcome the issue with an input that is not acceptable. Alternatively, a notification may state an action taken, automatically and independent of user input (e.g., based on one or more protocols), by the controller to overcome the problem with the input. When step 189 is complete, the process reverts to step 182.

In step 161, implementation of the P&IDs is organized. Implementation of the P&IDs may include, but is not limited to, process drawings, electrical drawings, schematics, control logic, mechanical drawings, Implementation of the P&IDs may be organized by the controller using a control engine, a communication module, one or more protocols, and/or stored data. When step 161 is completed, the auto-generated drawing is saved in an appropriate folder (e.g., a SPID folder) and the process proceeds to the END step.

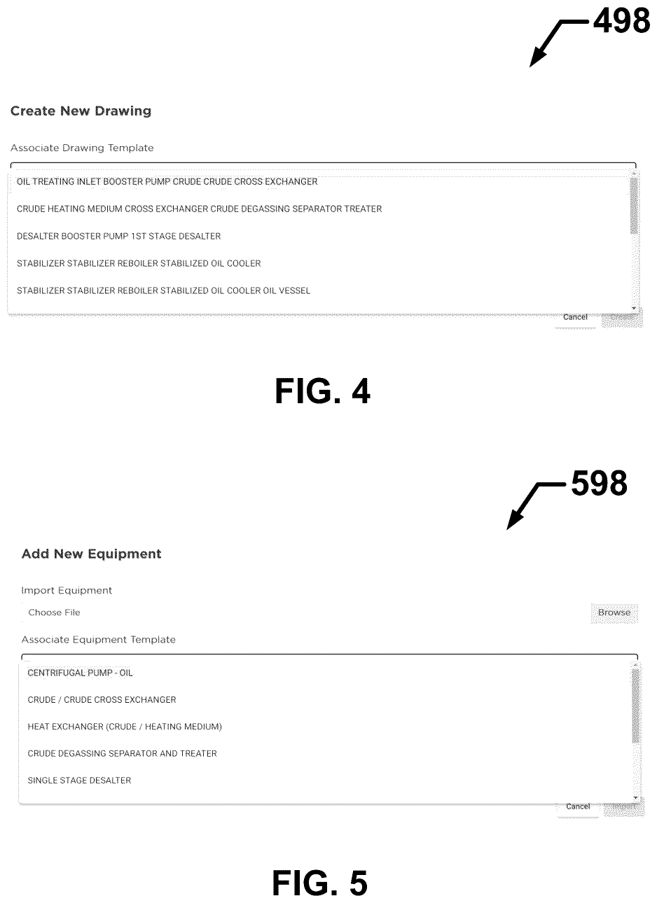

FIGS. 4 through 38 show examples of screenshots (or portions thereof) of pages that may be presented to a user by the web based application of the auto generation P&ID system according to certain example embodiments. Referring to the description above with respect to FIG. 1, the web based application is configured to auto generate system level P&IDs based on the templates (e.g., part of stored data) and design logic (part of protocols and algorithms) within the storage repository. The web based application, using custom-made pages, guides a user through feature selections (e.g., inputs) based on the system level design logic sheets stored in the storage repository and generates a set of P&IDs with the required features based on the inputs.

The web based application is configured to auto-generate system-level P&IDs from the design logic and other algorithms and protocols. This objective may be achieved by the web based application, which eliminates the need for reliance on spreadsheet logic. The interface of the web based application effectively considers the selections of (inputs received from) the user and autogenerates one or more P&IDs based on the inputs. Example embodiments can provide consistency and standardization across all generated P&IDs, decreased design cycle time through automation, cost reduction in project life cycle (e.g., engineering, execution, operation, maintenance), increased project predictability, and facilitated integration with other digital products.

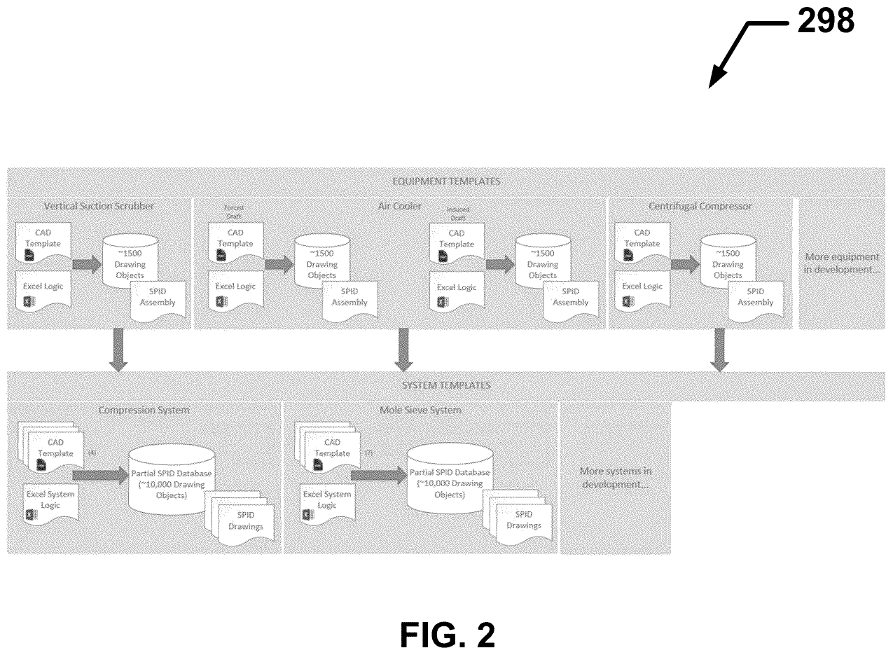

FIG. 2 shows a diagram 298 depicting the overall strategy for templates using the web based application according to certain example embodiments. The diagram 298 shows the process to translate engineering design logic and drawing templates into smart P&ID drawing objects and assemblies. Referring to the description above with respect to FIG. 1, the top tier of the diagram 298 of FIG. 2 represents the equipment level, and the bottom tier of the diagram 298 of FIG. 2 represents the system level (e.g., system templates, system tables, system drawings). A user can mix and match templates at the equipment level, and the assembly of templates can be used to design a P&ID system. For example, the leftmost portion of the top tier of FIG. 2 may be or include an equipment-level P&ID (tables, templates, etc.).

Equipment templates (types of pages) may be based on the CAD templates and spreadsheet-based equipment logic provided by one or more suppliers and/or retrieved by the P&ID system (e.g., from a vendor, from a website, from a government or regulatory entity, from an industry group). The equipment templates may contain a large number (e.g., over 500, over 1500) of drawing objects. Standard P&IDs and related assemblies may be created based on the equipment templates for easy placement and compatibility with the applicable code. System level drawing templates (part of stored data) may be incorporated into standard P&IDs based on the CAD templates and spreadsheet system logic provided by one or more suppliers (e.g., engineering groups). The web based application may also contain equipment level templates developed by one or more suppliers. The web based application may contain a partial standard P&ID database (e.g., over 5,000 drawing objects, over 10,000 drawing objects) and generate all of the P&IDs needed for a complete system.

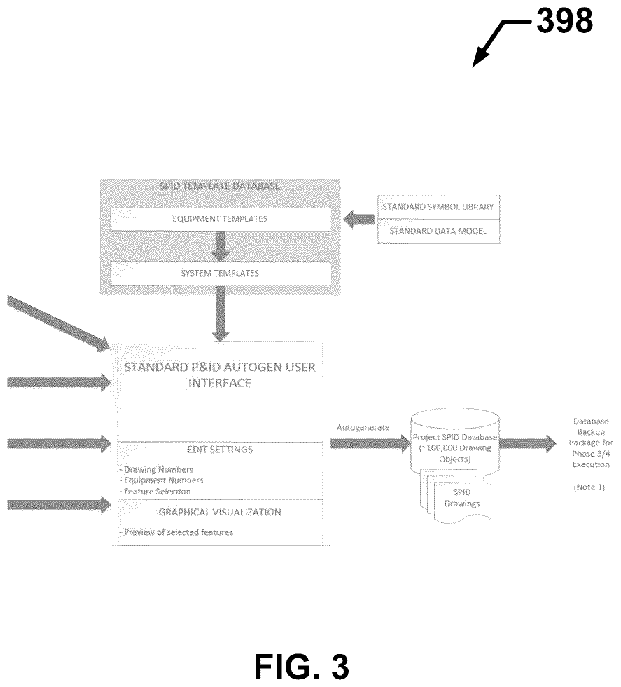

FIG. 3 shows a diagram 398 depicting the overall strategy for projects using the web based application according to certain example embodiments. The diagram 398 shows an example project strategy including possible engineering inputs from various engineering systems and a workflow for a project user to initiate auto-generation of required P&IDs. Multiple feeds/inputs of data (e.g., process flow diagrams for different systems, templates for different equipment options, templates for different subassemblies, design logic, symbol libraries) may go into a project playbook, which is not defined in the current art. The project playbook may be passed onto the web based application, where the settings (e.g., drawing numbers, equipment tags, feature selection) may be edited for generation. The web based application may be used for quicker, easier development of standardized P&IDs and may allow for a “print preview” of selected features before drawing generation. The example web based application also takes into account the equipment and system templates from the standard P&ID template database (part of stored data). The web based application may auto-generate the standard P&IDs along with a partial standard P&ID database (part of stored data).

The web based application may be organized in any of a number of ways. For example, the web based application may be divided into 3 sections: “Home” (the landing page), “projects”, and “library”. In such a case, the home page may be where general information about the web based application is available. There may also be a link to a playbook as well as some contact information. The Library level is where systems may be created based on spreadsheet system and equipment design logic files provided by one or more suppliers (e.g., engineering teams). Drawing templates may be associated with the different drawings within the system, and each drawing template (part of stored data) may have different instances of equipment associated with equipment templates (part of stored data).

The Project level is where a user may provide inputs (e.g., make selections on a page), (e.g., equipment-level inputs, system-level inputs) that are subsequently used by the web based application to generate P&IDs. Standard P&IDs allow a user to build out a configuration with certain features of a system without affecting the system library. When configuring a Project, the web based application may offer a select menu for making changes to the design logic at both the system level and equipment level. Once a project has been fully configured, and the user chooses to begin drawing generation, the web based application may send a request to an application server (e.g., the network manager, another part of the auto generation P&ID system, part of the controller) to begin the process. The application server may create the required new P&IDs, open each newly created P&ID, place drawing-level assemblies, remove unselected features from a P&ID, and save and close the P&ID.

FIG. 4 shows a screenshot 498 depicting a page for a drawing template configuration using the web based application according to certain example embodiments. In the “Create New Drawing” dialog, the Associate Drawing Template section lists all available Drawing Templates that can be used as part of a System in the System Library or in a Project. These templates are pre-drafted “assemblies” in that the web based application may use when generating P&IDs.

FIG. 5 shows a screenshot 598 depicting a page for an equipment template configuration using the web based application according to certain example embodiments. In the “Add New Equipment” dialog, the Associate Equipment Template section lists all available Equipment Templates that may be used as part of a system in the System Library or in a Project. These templates may be associated with equipment level design logic provided by a supplier (e.g., an engineering team) and may be used multiple times in the same system for different instances of equipment that are defined by the same “template”.

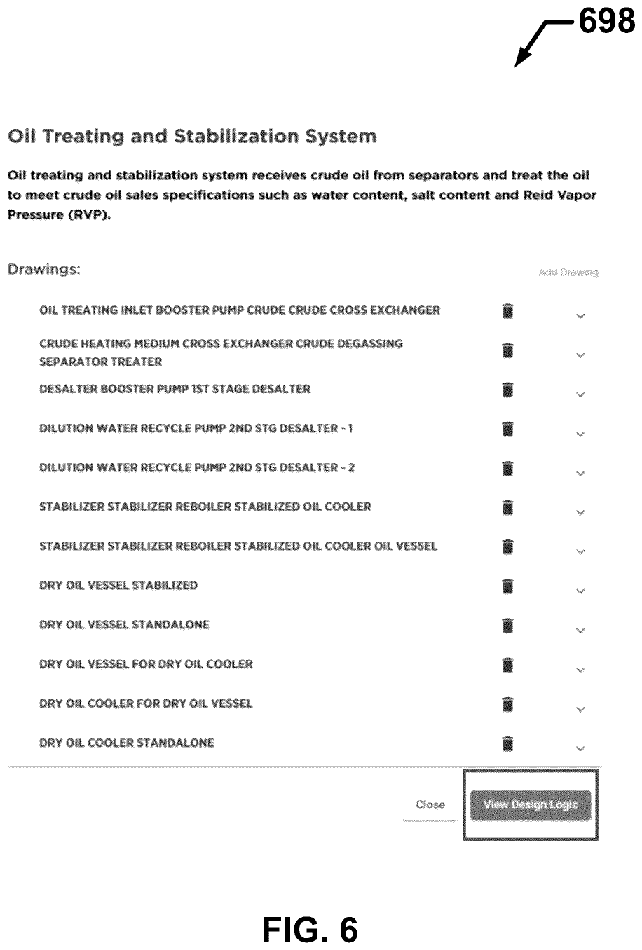

FIG. 6 shows a screenshot 698 depicting a page for a system library configuration using the web based application according to certain example embodiments. The System Library may be a collection of some or all of the available systems that may be used to generate P&IDs. By clicking on a system's card, a user may be shown information about the system. To view the design logic and assumptions of the system, a user may click on the “View Design Logic” button at the bottom of the page to pull up additional information. The user may also expand a system to see the drawings that are contained within the system and the equipment instances associated with each drawing. By clicking on the system design logic, users may view information that includes, but is not limited to, the Function, Feature Summary, Design Logic, and Assumptions.

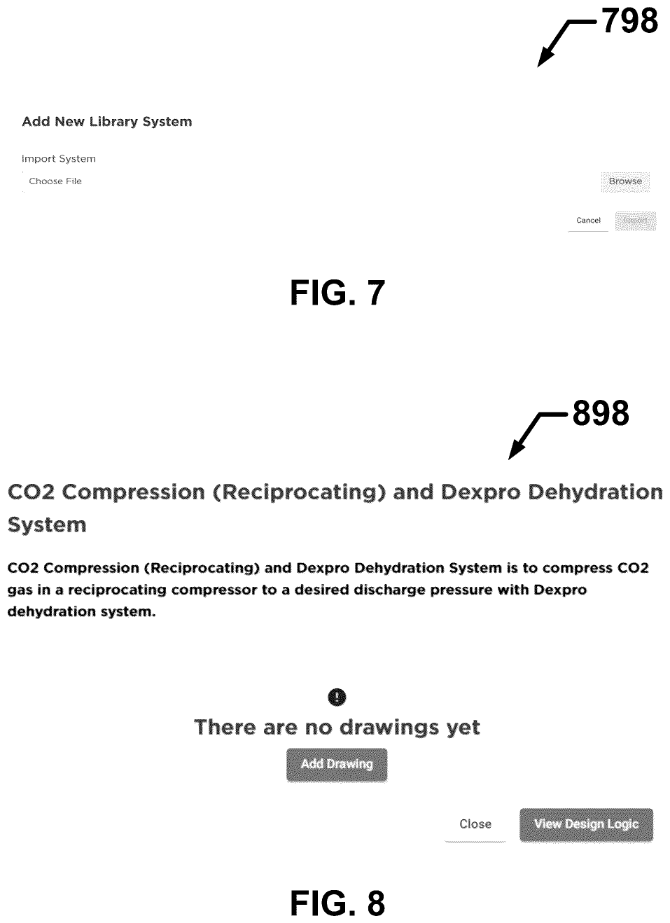

FIG. 7 shows a screenshot 798 depicting a page for a library system import dialog box using the web based application according to certain example embodiments. In some cases, importing any systems, equipment, or creating drawings may only be done as a user with administrative privileges. Once a system has been added, it may be available for use when creating a project or system in the project's section of the web based application. A user may be able to delete any existing systems that are in the library. To create a system, a user may simply click on an “Add System” link (a form of input) on a page. A user may see a dialog box on a page where the user may import an existing file associated with the system.

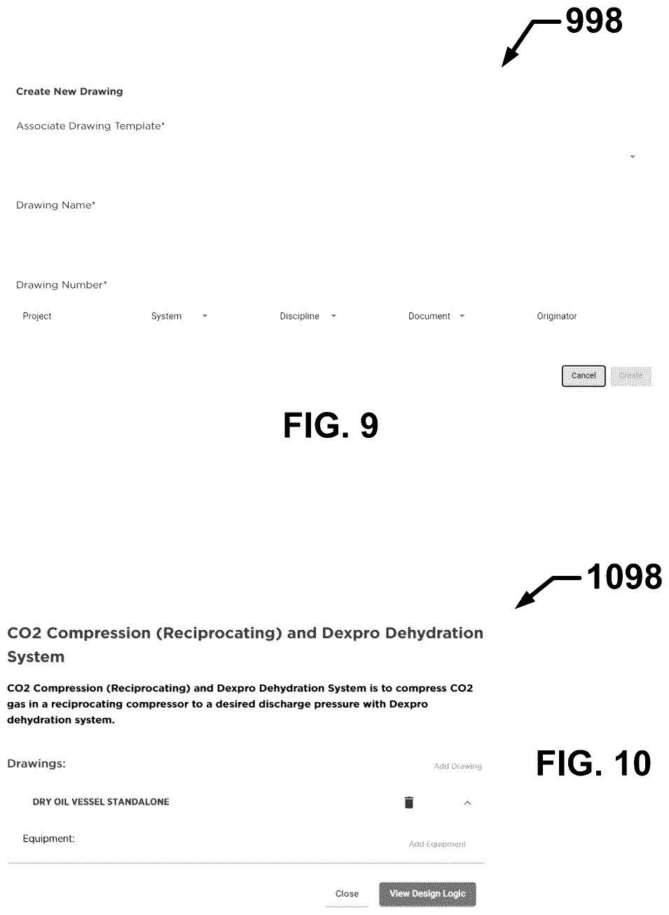

FIG. 8 shows a screenshot 898 depicting a page that includes a library system information dialog box with no drawings using the web based application according to certain example embodiments. FIG. 9 shows a screenshot 998 depicting a page that includes a drawing creation dialog box using the web based application according to certain example embodiments. FIG. 10 shows a screenshot 1098 depicting a page that includes a library system information dialog box for newly created drawings using the web based application according to certain example embodiments. To add a new drawing and equipment, a user may click on the “Add Drawing” button (a form of input). This may bring up a new dialog box with a drop down to select the associated drawing template and an input to name the drawing. A user may be able to set the associate drawing template, name, and the standard drawing number. A user may then see the new drawing under the system summary with no equipment.

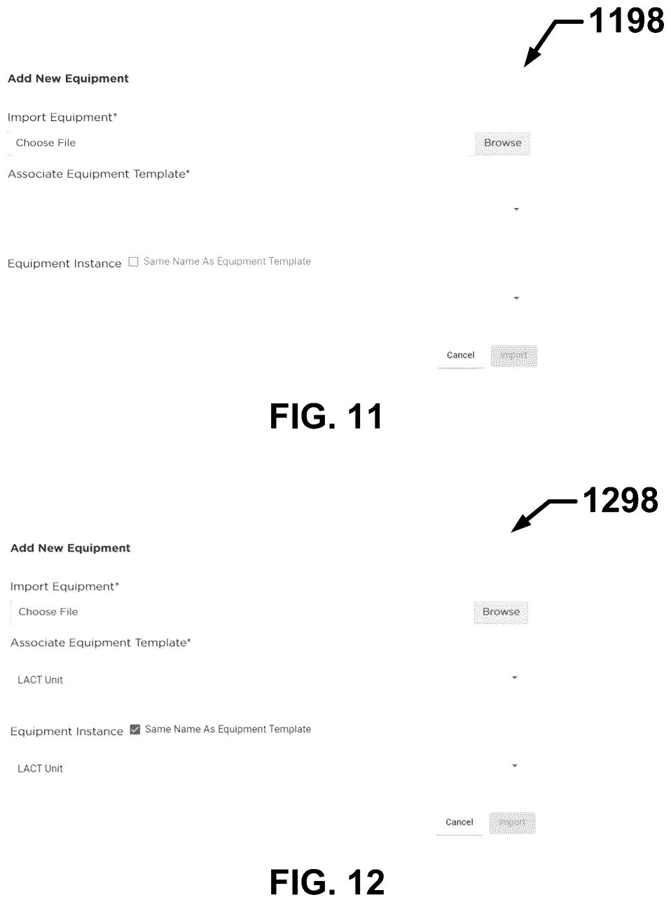

FIG. 11 shows a screenshot 1198 depicting a page that includes a library system equipment upload dialog box using the web based application according to certain example embodiments. FIG. 12 shows a screenshot 1298 depicting a page that includes an equipment template and equipment naming instance dialog box using the web based application according to certain example embodiments. To add equipment, there is an “Add Equipment” link available once a user has successfully created a new drawing (e.g., a new P&ID). This link will take a user to a new dialog box (a new page) where a user may import equipment data. A user may need to associate the equipment data with one of the existing equipment templates in the drop down as well as selecting (an input) the appropriate equipment instance on the page. Like the system import, it may be assumed that the user has existing equipment data to upload. Equipment templates and instances may be paired to each other by the controller or by a user. If the equipment instance and the template are identical then the user may select the available check box to automatically set identical names. If the check box to set identical names is greyed out, then the system design logic does not describe any equipment templates with the same name equipment instances.

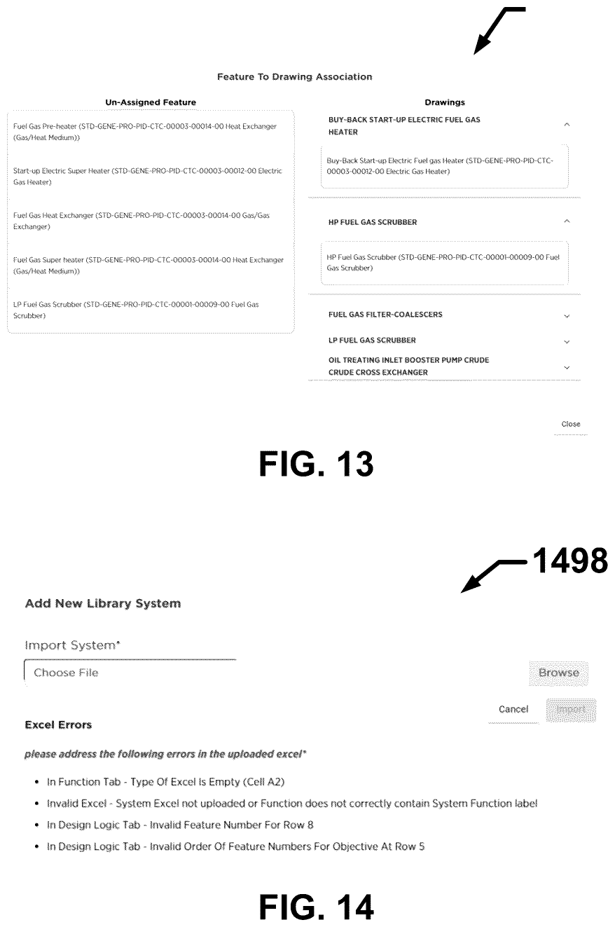

FIG. 13 shows a screenshot 1398 depicting a page that includes an equipment template and equipment naming instance dialog box using the web based application according to certain example embodiments. The page with the system library details may include a button to associate features for equipment described by the system information that was imported. The features may be associated with any of the drawings that are created and assigned to the selected system. This association may be used for identifying what drawings are being used according to the feature selection at the project level. The popup form (a type of page) may showcase the system features and an expandable drawing list to show what is currently assigned to that drawing. A user may click and drag over all the features to their respective drawings on the page. These assignments may affect the project level drawing details.

FIG. 14 shows a screenshot 1498 depicting a page that includes a dialog box for validation errors using the web based application according to certain example embodiments. When importing data for a system or equipment, a user may encounter some errors in the data (e.g., a spreadsheet) that may break the proper generation and parsing. The example web based application includes a validation check at every attempt to import data for either a new system or new equipment. The web based application may be configured to catch any errors in the data and display the errors at some location (e.g., at the bottom of each import form) on the page. Such a feature may assist a user in fixing any errors with the data based on current applicable standards.

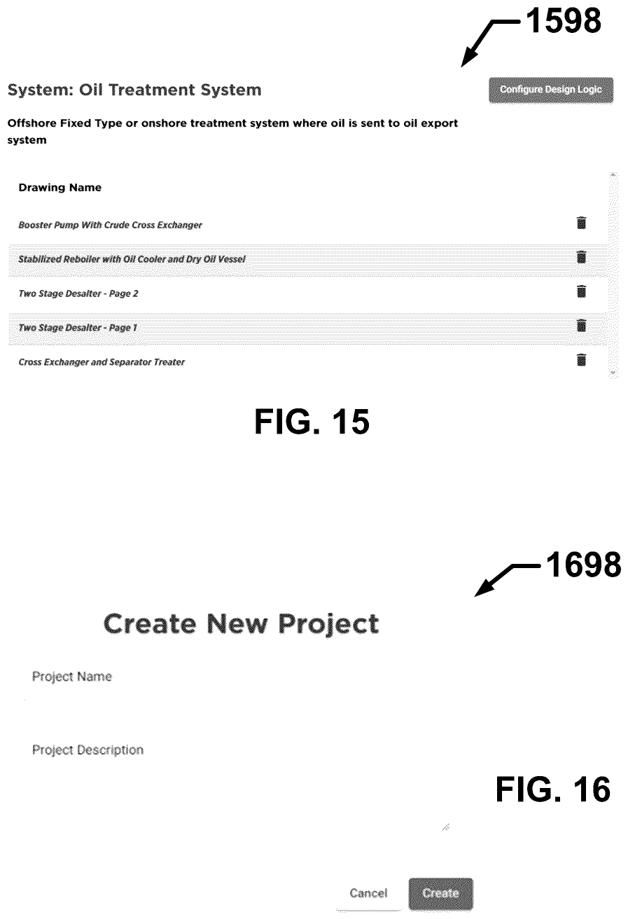

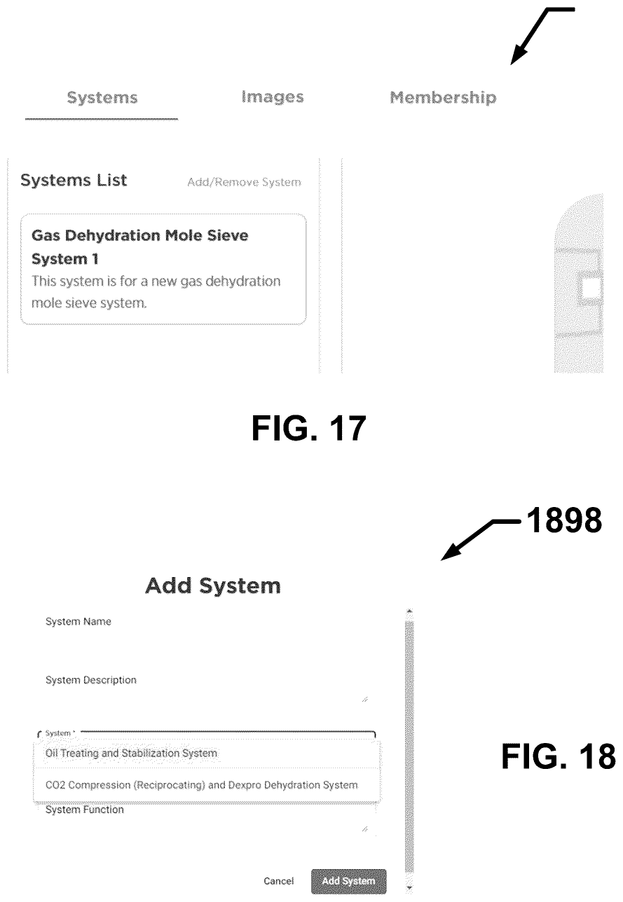

FIG. 15 shows a screenshot 1598 depicting a page that includes a project system feature configuration using the web based application according to certain example embodiments. FIG. 16 shows a screenshot 1698 depicting a page creating a new project using the web based application according to certain example embodiments. FIG. 17 shows a screenshot 1798 depicting a page adding a system to a project using the web based application according to certain example embodiments. FIG. 18 shows a screenshot 1898 depicting another page adding a system to a project using the web based application according to certain example embodiments.

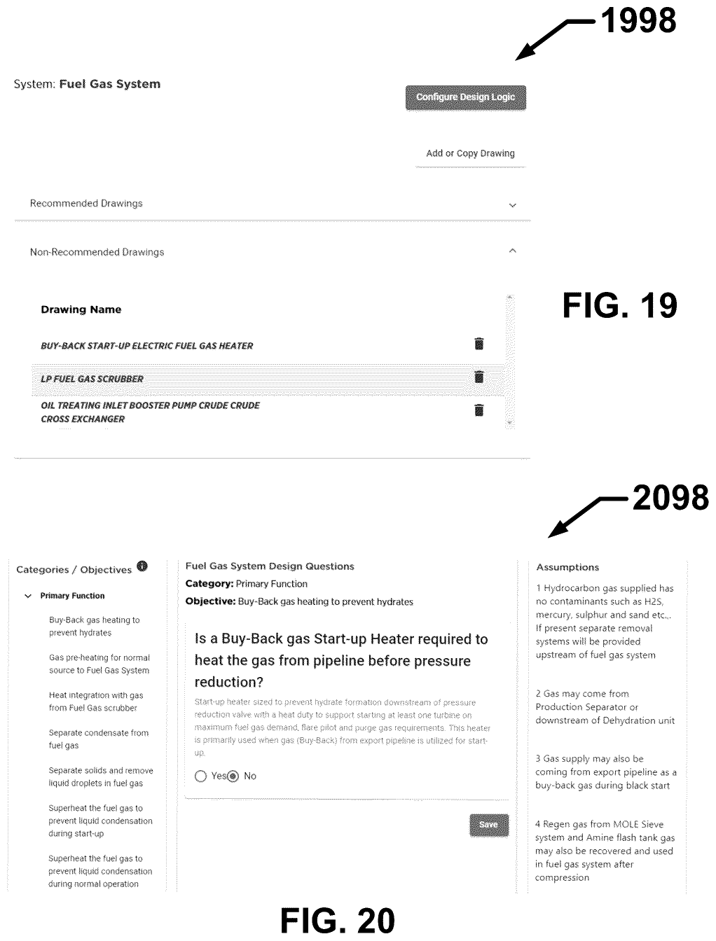

FIG. 19 shows a screenshot 1998 depicting another page that includes a listing of non-recommended drawings using the web based application according to certain example embodiments. Once a user adds a new system to a project, the user may click on the system (a type of input) and see the details of the associated drawings. The page in FIG. 19 has two sections, which includes a Recommended Drawings list and a Non-Recommended Drawings list. These two distinctions are based on the default feature selections on the system design logic for the web based application. This helps organize and show only the drawings that are being used by the system. For instance, the screenshot 1998 shows a “Buy-Back Start-Up Electric Fuel Gas Heater” in the list of Non-Recommended Drawings.

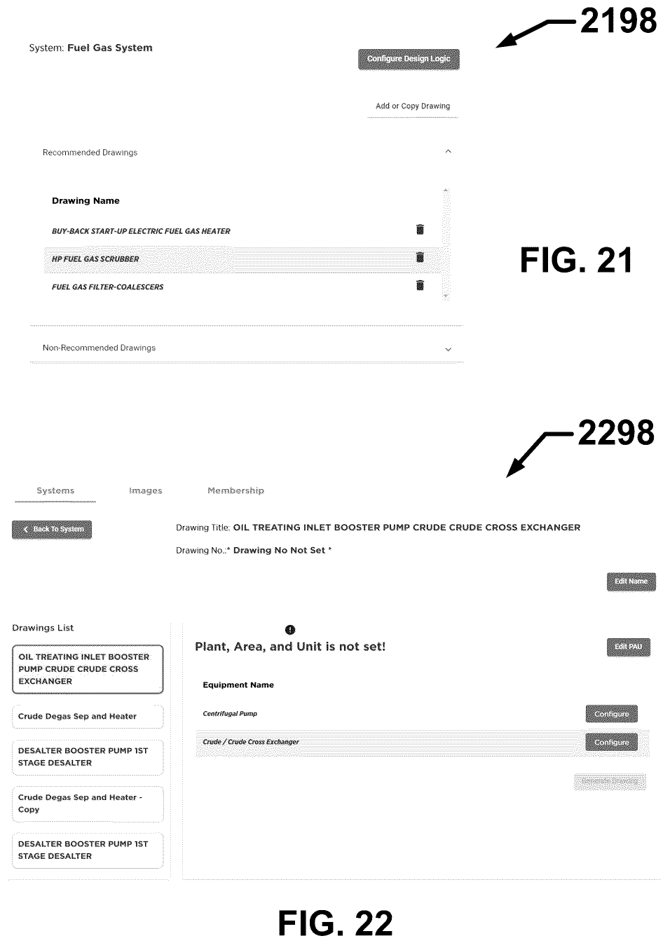

FIG. 20 shows a screenshot 2098 depicting another page that includes an associated design logic question using the web based application according to certain example embodiments. In this configuration for the system (e.g., can be viewed when a user clicks on the “Configure Design Logic” button on the screenshot 1998 in the top right corner), a user may be presented with a page as captured in the screenshot 2098 of FIG. 20, in which the question “Is a Buy-back gas Start-up Heater required to heat the gas from pipeline before pressure reduction?” is presented. The user in this case has an input of “No” on the page in this case. If the user switches the input to “Yes”, then the drawing associated with the “Buy-Back Start-Up Electric Fuel Gas Heater” is saved, and the associated drawing is then among the recommend drawing list, as shown in the screenshot 2198 of FIG. 21.

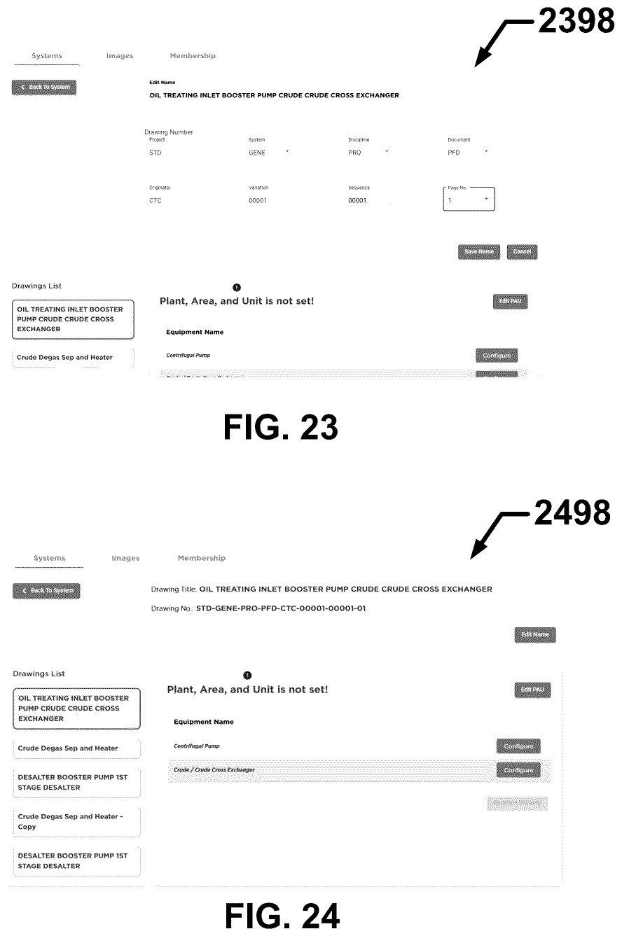

FIG. 22 shows a screenshot 2298 depicting another page that includes project drawing details using the web based application according to certain example embodiments. FIG. 23 shows a screenshot 2398 depicting another page that includes editing a drawing number using the web based application according to certain example embodiments. FIG. 24 shows a screenshot 2498 depicting another page that includes a saved drawing number using the web based application according to certain example embodiments. When a user has a new drawing, the drawing details may include the Drawing Title, Drawing No., and the Plant/Area/Unit section followed by the list of equipment that the selected project drawing includes. The drawing number and Plant/Area/Unit in this case are selected in order to generate the drawing. To edit the title and drawing number, a user may select the “Edit Name” button on the page.

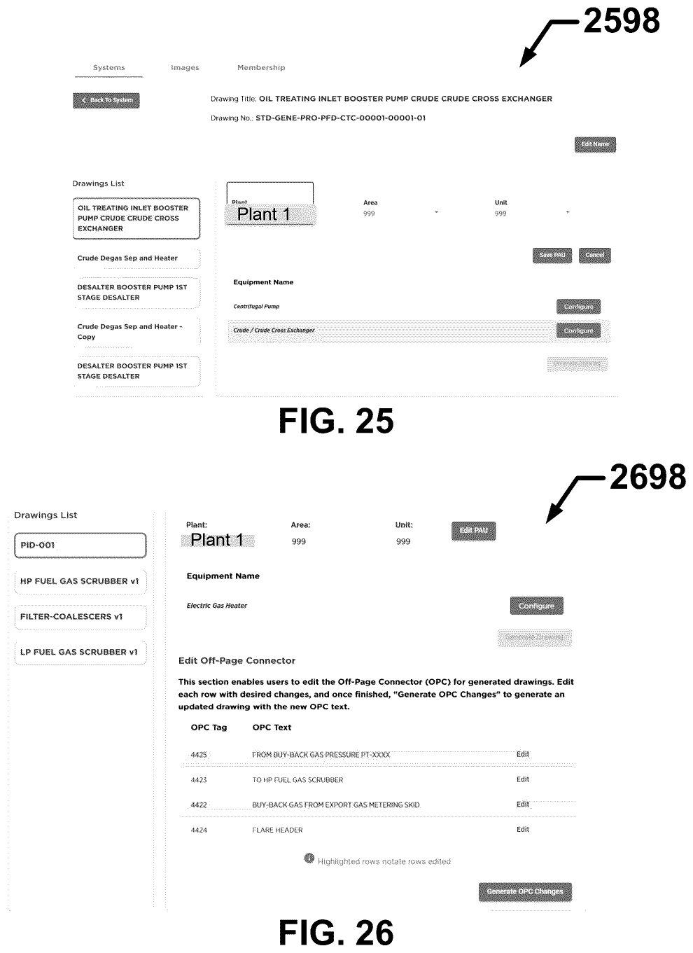

FIG. 25 shows a screenshot 2598 depicting another page that includes configuring a drawing in a project using the web based application according to certain example embodiments. To configure a drawing's Plant/Area/Unit, a user selects (inputs) the drawing to be configured and clicks on the “Edit PAU” button to access the dropdown menus for plants, areas, and units.

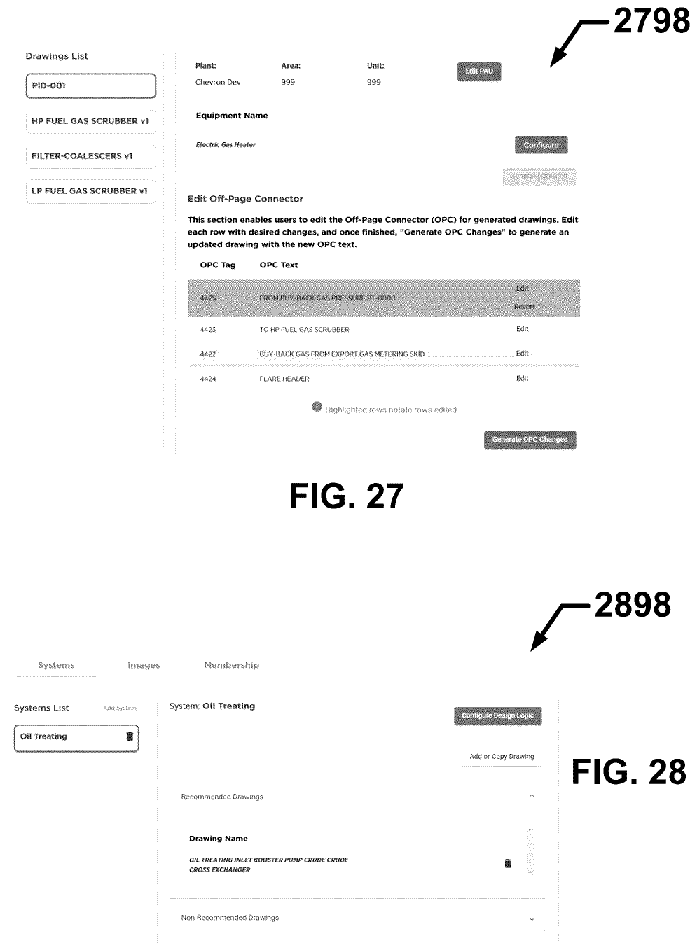

FIG. 26 shows a screenshot 2698 depicting another page that includes editing an off-page connector form using the web based application according to certain example embodiments. FIG. 27 shows a screenshot 2798 depicting another page that also includes editing an off-page connector form using the web based application according to certain example embodiments. Inside a drawing in a project system may be a section to edit Off-Page Connectors (OPC), in this case located just below the list of available equipment for that drawing. The OPCs relate to the text associated with the end connectors for the outputted drawing after the user decides to generate it. A user may select “Edit” next to the OPC that is to be edited. A text box may open for input from the user. Once the user saves the changes by clicking “Done”, the row is highlighted to indicate that an edit was made, as shown in the screenshot 2798 of FIG. 27. A user may then click “Generate OPC Changes” to generate the drawing.

FIG. 28 shows a screenshot 2898 depicting another page that includes adding or copying a drawing using the web based application according to certain example embodiments. Once a system is added to a project, a set of default drawings associated with the system chosen may be available. In some cases, these drawings are what were imported on the creation of the system by the user. The default drawings may be viewed by a user in the library section. In order to add new drawings from scratch or copy a new drawing from an existing one in the current project, a user may select the “Add or Copy Drawing” button in the system detail's view.

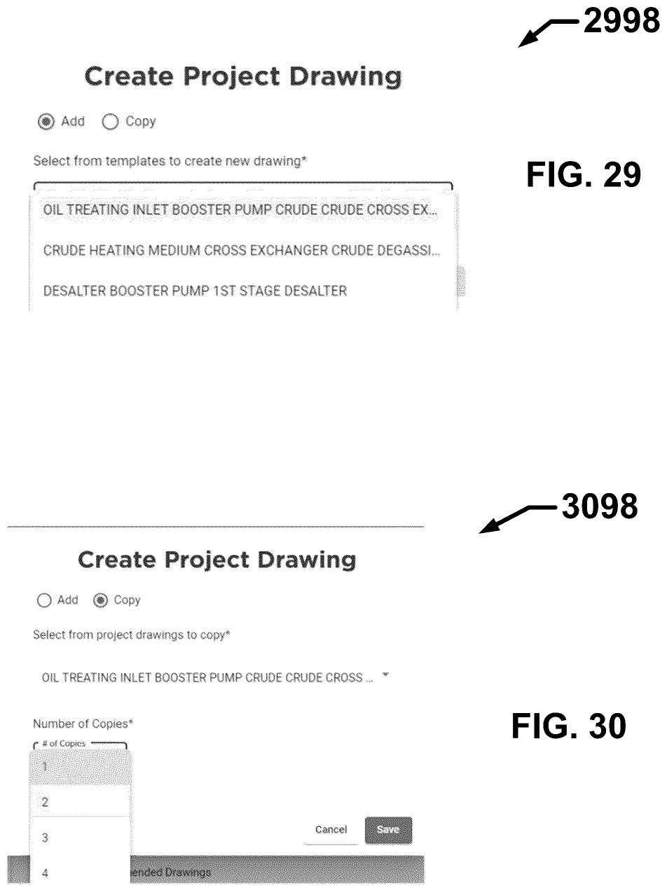

FIG. 29 shows a screenshot 2998 depicting another page that includes adding a new drawing using the web based application according to certain example embodiments. A new dialog pop up box may present itself with the option to either add a new drawing or copy from an existing one. To add a new drawing, a user may select the Add option if not already set, select a drawing template from the drop-down menu, and then select Save.

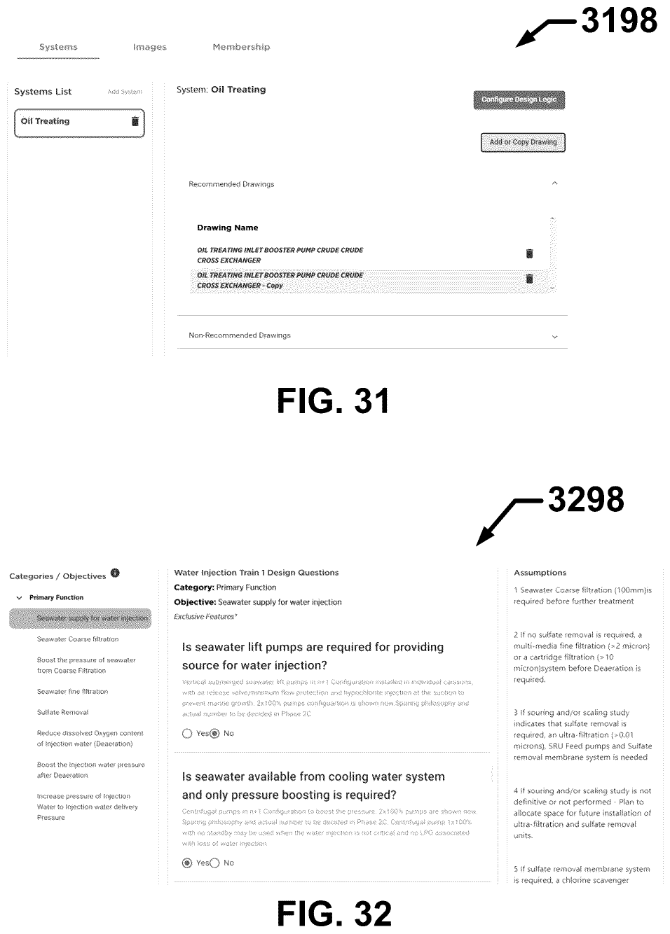

FIG. 30 shows a screenshot 3098 depicting another page that includes copying an existing drawing using the web based application according to certain example embodiments. FIG. 31 shows a screenshot 3198 depicting another page that includes successful copying of a drawing using the web based application according to certain example embodiments. To copy a drawing, a user may select the Copy option at the top of the screenshot 3098. The resulting drop down menu may only show the drawings that are existing in the current project. A user may select the desired drawing to copy. There is an additional option for selecting how many copies of the drawing a user would like in a similar drop-down menu. Once selected, a user may save those selections by clicking “Save”. If the copy is successful, the user sees the new drawing presented in the system details with a “-Copy” attached to the drawing name. The user may then go into the drawing and configure as normal.

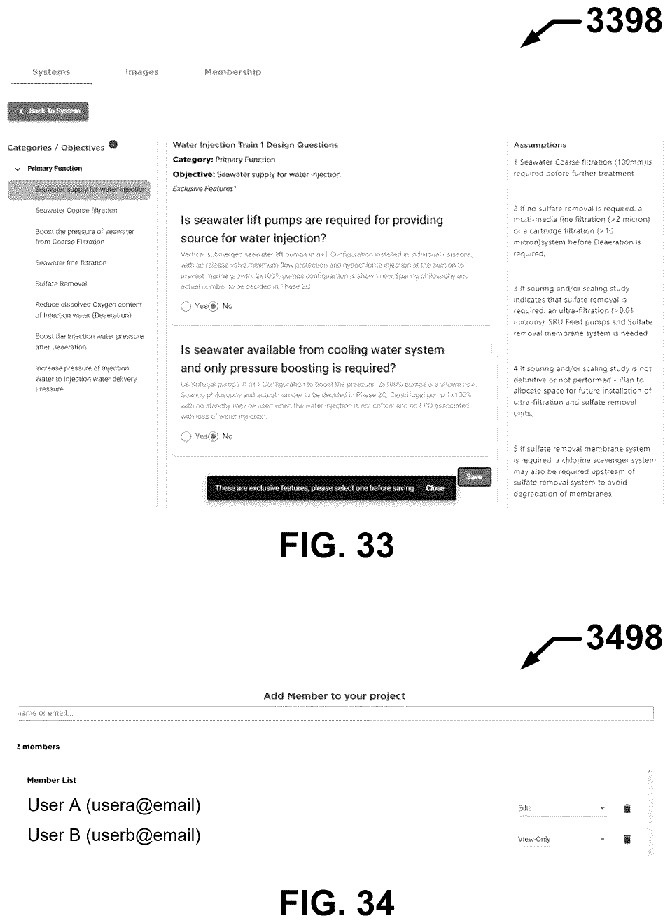

FIG. 32 shows a screenshot 3298 depicting another page that includes a project system design logic configuration using the web based application according to certain example embodiments. FIG. 33 shows a screenshot 3398 depicting another page that includes a project system design logic configuration with an exclusive feature error using the web based application according to certain example embodiments. Once a system has been added to a project, feature selections may be made to configure the Standard P&IDs to fit the project requirements. To view system level features and design logic, a user may click on the system card inside the project. The user may then click on “Configure <your system name here>”, which brings up the system design logic for that system. The user may make selections to turn on and off features by walking through the series of questions.

To view equipment level features and design logic, a user may navigate down to an equipment instance with the system/drawing of interest in the project. A user may then click on the “Configure” button on the page next to the equipment that for which the user wants to access the design logic. The interface in this case is the same as for the system level selections. A user may make selections to turn on and off features by walking through the series of questions.

If a category contains exclusive features, then there may be a label at the top indicating the features, as seen in the screenshot 3398 of FIG. 33. An exclusive feature indicates that only one feature question may be selected “Yes” out of the listed feature questions. When selecting a feature question to “Yes” the application may automatically switch all other questions to “No”. However, if a user selects “No” on a question, the web based application may leave other questions unmodified in case the user makes other changes before saving. Thus, there may be a case where a user tries to save a selections when all feature questions are selected as “No”, in which case an error message appears, as shown in the screenshot 3398 of FIG. 33, indicating that at least one question must be “Yes”.

FIG. 34 shows a screenshot 3498 depicting another page that includes a project membership tab using the web based application according to certain example embodiments. Each project may be protected by only allowing the members of the project (and administrators) to have access to it. Memberships may be managed in the “Membership” tab when a user is inside a project. The membership tab may consist of a search bar and the current list of members of the project. Whoever initially makes the project may automatically be added to the member list, and he/she needs to add more members to the list.

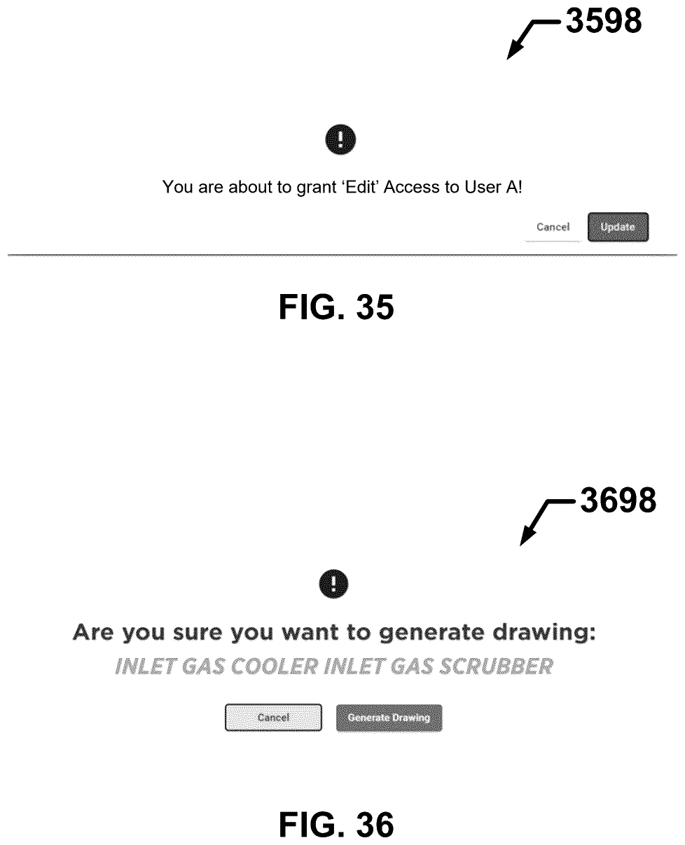

FIG. 35 shows a screenshot 3598 depicting another page that includes a dialog box to grant edit access to a member using the web based application according to certain example embodiments. Once a member is added to the list, the member may have access to the member list and may further add or remove individuals. Each member may have an access role associated with their membership. In this case, there are two types of access for a project member: “Edit” or “View-Only”. A member may change the type of access by clicking the drop down menu. When switching someone from view-only to edit, a user may be prompted with a validation dialog box to verify that the member will be allowed to edit the project.

FIG. 36 shows a screenshot 3698 depicting another page that includes a dialog box to confirm the generation of a drawing using the web based application according to certain example embodiments. Once a project has been fully configured, a user may navigate to a particular drawing to generate. The user may click the “Generate [your drawing name]” button located on (e.g., in the bottom right corner) the page of the web based application to send the generation command to the server. An alert dialog box may appear, as in the screenshot 3698 of FIG. 36, to confirm because once the drawing is sent to be generated the process may not be canceled. A user may be automatically sent to the images tab where the user may view any completed images. Drawings within a project may need to be named and assigned a Plant, Area, and Unit corresponding to the standard P&ID PAU structure where the drawings are to reside. A user may click on “Configure” next to the system drawing to see the PAU information above.

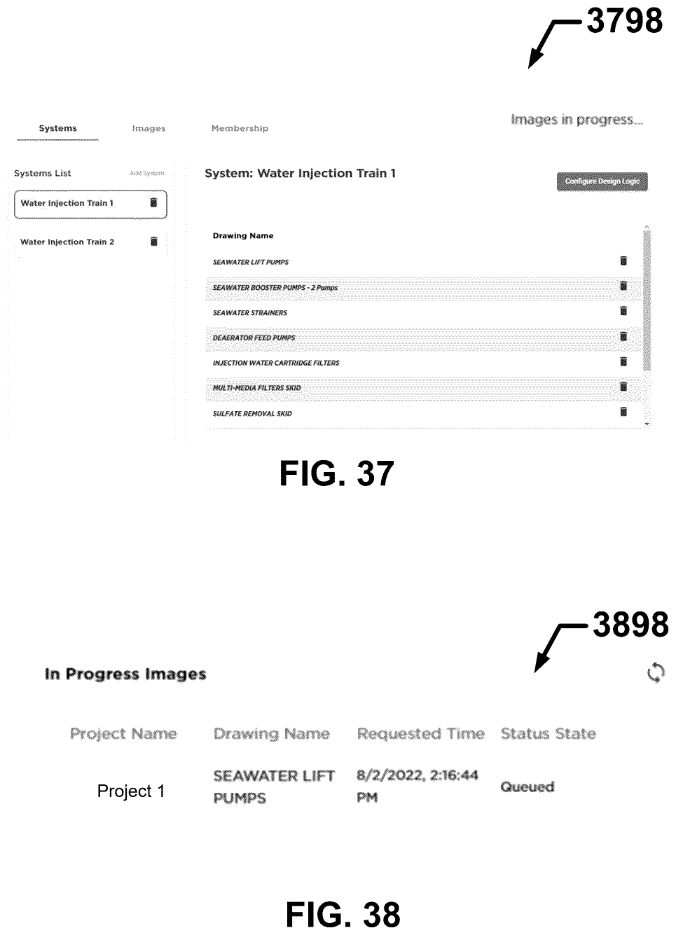

FIG. 37 shows a screenshot 3798 depicting another page that includes in progress images notification using the web based application according to certain example embodiments. FIG. 38 shows a screenshot 3898 depicting another page that includes in progress images side bar information using the web based application according to certain example embodiments. After receiving a drawing to be generated from a user, the web based application may generate a notification (e.g., on the top right corner of the screenshot 3798) indicating that there is a drawing(s) that are in progress of being generated. This notification may be viewable from all areas of the web based application. If a user clicks on the notification, a side bar may appear on the page showing additional information about any images in progress.

Viewable information may include the project name, the drawing name, the time the drawing was requested to be generated, and the status of the drawing. The drawing may be in one of 4 different status states: “In Progress”, “Queued”, “Complete”, or “Error”. There may also be a refresh button on the top right of this side bar that a user may periodically click to manually refresh the statuses of the images if there have been any subsequent changes. Once an image is completed or errored out, the image may automatically be removed from the side bar menu. A user may be able to view the completed or errored out images in the “Images” tab in the associated project from they were generated.

To view the drawings in a Project from the web based application, a user may navigate to the images tab at the home screen for the project of interest. This page may include a table that lists all the drawings that have been completed. For completed drawings, the “Drawing Image Path” column may show where the generated drawing exists in the standard P&ID. When the user clicks on a row in the table for a drawing that has been generated, a preview of the image may be shown, and the user may have the option to download the image. All drawings generated in a standard P&ID may be available to view and edit in the standard P&ID plant that the user specified for their project.

An user with administrative access may access the “Admin” section of the web based application, where the user may handle Plant, Areas, Units, Equipment Templates, and Drawing Templates. These elements are important to link drawings with other programs. The Plant, Areas, and Units, also known as PAUs, may associate the project drawings with a file-like structure and hierarchy in other programs. The drawing and equipment templates may be important, as they may include information passed to the drawing generation service to link with the needed assemblies in other programs. Once a component is expanded, the table may show relevant information for that component and may include functionality to navigate and modify the information. Specifically, a user may be able to filter, add, edit, delete, count, and navigate. In some cases, some or all of the functionality described above may be performed when the user system of a user is offline. In such cases, the user system may use pages uploaded to the user system from the web based application before the user system and/or the web based application goes offline.

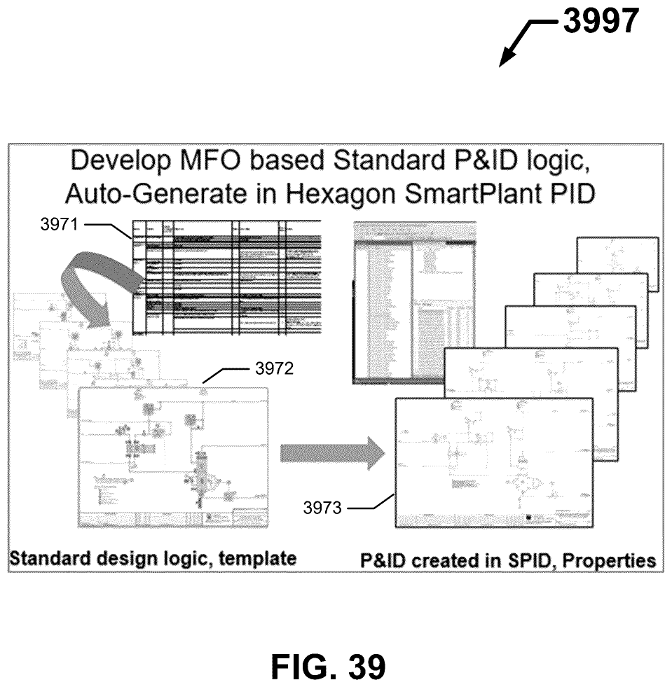

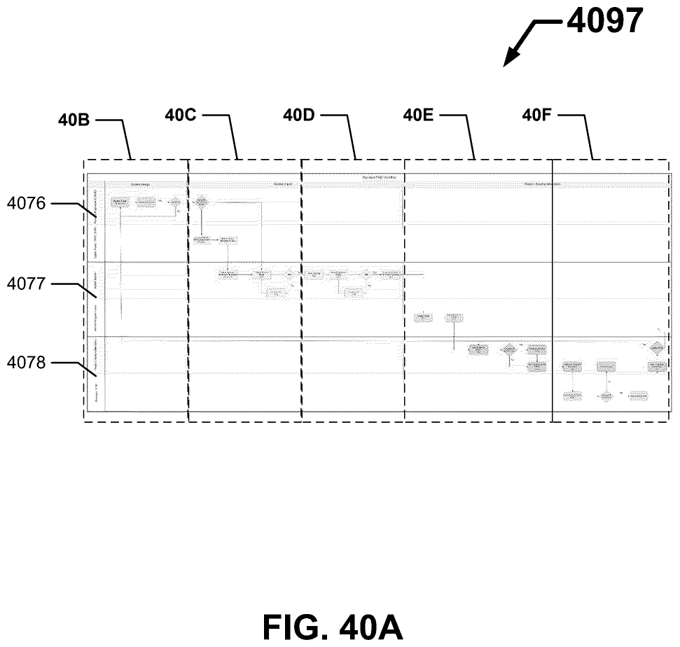

FIG. 39 shows an overall process flow diagram 3997 involving a P&ID system according to certain example embodiments. The process flow diagram 3997 illustrates steps of developing design logic, translating it to engineering drawing templates, and passing those on to a web based application for auto generation of smart P&IDs. Referring to the description above with respect to FIGS. 1 through 38, the process flow diagram 3997 starts with a development stage 3971, where the logic design is developed (e.g., by software engineers) and templates are generated. Templates may be generated and maintained for individual pieces of equipment (e.g., pumps, motors, piping, vessels, meters, valves), assemblies, subsystems, systems, some other level of granularity within a system, or any suitable combination thereof. Also, in the development stage 3971 protocols (e.g., communication protocols, procedures, translation protocols for templates, interface with the web application, interface with a user system) are generated and maintained. In the digital stage 3972, the templates and logic of the development stage 3971 are converted into digital representations (e.g., a digital output) that are configured to allow for user interaction (e.g., on a web application), as represented by the arrow from the digital stage 3972 to the output stage 3973. The digital stage can store records of each design created, including each version of a design.

After a user enters parameters with respect to a particular project into the application (e.g., a web application), the output stage 3973 shows the results in the form of full or partial sections of a P&ID system that is designed based on the inputs. In some cases, a user may interact with the application further to revise (e.g., change one or more parameters for a project), refine, and/or otherwise alter the results shown in the output stage 3973. As an example, a user uses a web application interface, and then interfaces with a digital P&ID system to generate an output (e.g., one or more P&ID diagrams). In some cases, some or all of the drawings in the output stage 3973 can have an interactive feature that provides information and/or allows a user to modify a drawing (e.g., a piece of equipment, piping). For example, a drawing in the output stage 3973 can include or reveal information (e.g., nameplate data, cost, size, material, rating, serial number, model, manufacturer) about a particular piece of equipment (e.g., a pump, a motor, a length of pipe) in the drawing. One or more tables in the output stage 3973 may include some or all of the various properties of each piece of equipment and/or other component of a particular design.

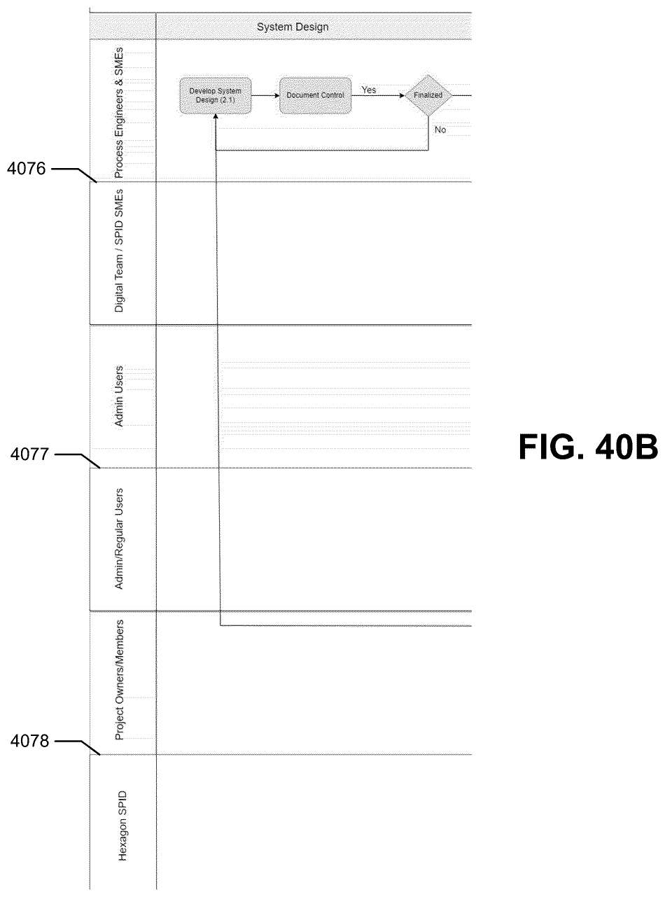

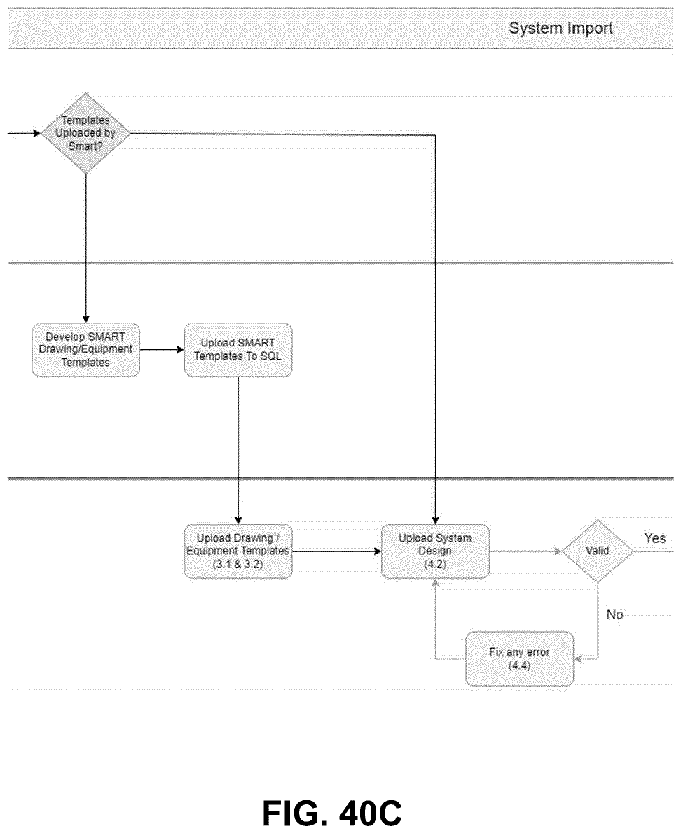

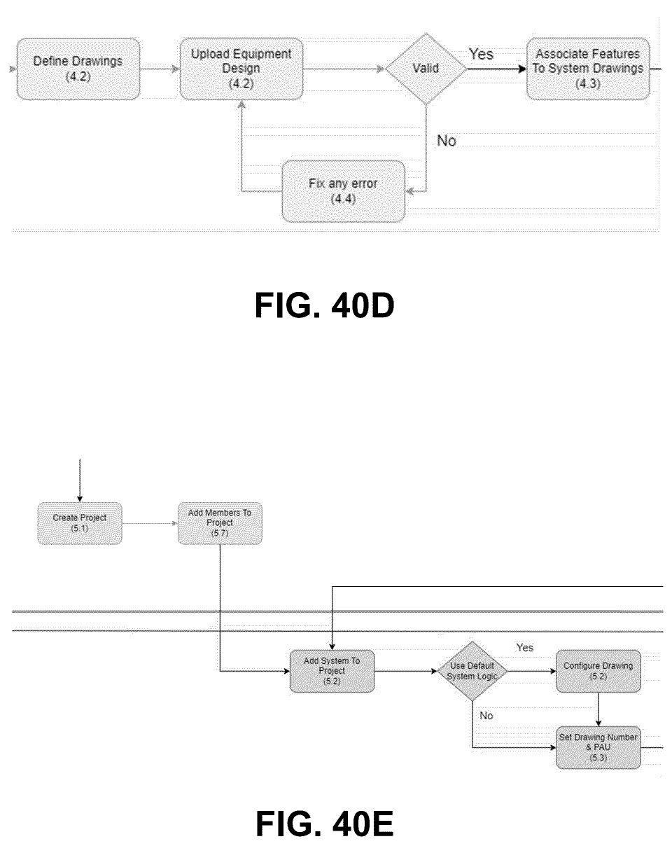

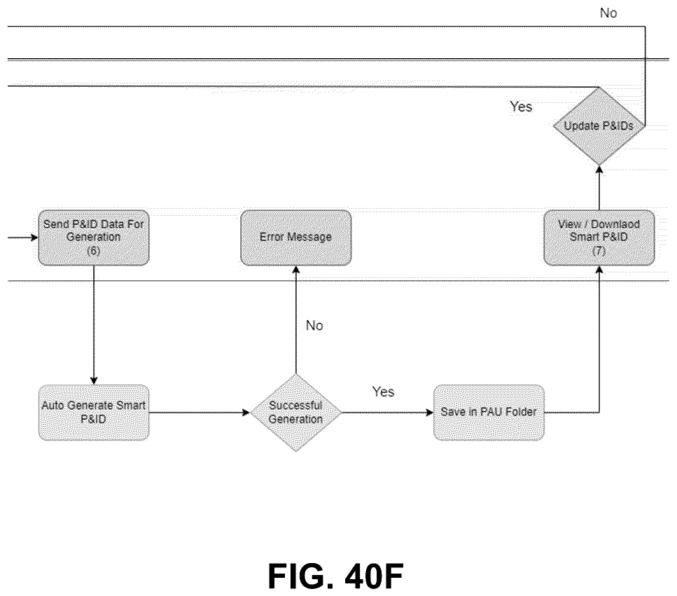

FIGS. 40A through 40F show a P&ID workflow diagram 4097 according to certain example embodiments. The P&ID workflow diagram 4097 shows different users and roles played by them and a sequence followed to: develop engineering artifacts (Engineers); screen and control documents (Document Control); develop, upload and validate templates into a web based application (Digital Team, Admin); create a project and members with appropriate rights to view/edit (Users); select system options and equipment with features (Users); and ultimately auto-generation of P&IDs in a smart P&ID environment. Referring to the description above with respect to FIGS. 1 through 39, the workflow diagram 4097 of FIGS. 40A through 40F show the work of three different groups: Process engineers and developers 4076 along the top third of the workflow diagram 4097, administrators 4077 along the middle of the workflow diagram 4097, and users 4078 along the bottom third of the workflow diagram 4097. The process engineers and developers 4076 generate and maintain the logic of the P&ID system. This allows for different systems (e.g., inlet separation, compression) to be designed, even to the equipment level. The work by the process engineers and developers 4076 also includes the generation and maintenance of the various templates used in the P&ID system.

Some of the work by the process engineers and developers 4076 may be geared toward standardization and using minimal functional objectives. In this way, a project that is being developed using the P&ID system in one part of the world for a particular application may have a design that is substantially the same as the design of another project that is being developed using the P&ID system in another part of the world. In some cases, a template may initially be generated by one or more of the process engineers and developers 4076.

Some of the activity by the process engineers and developers 4076 is in the left column (corresponding to system design) of the workflow diagram 4097, with the remainder of its activity transitioning in the middle column (corresponding to system ingest) of the workflow diagram 4097. In the middle column, process engineers and developers 4076 (e.g., digital team) take what was developed in the left column and translate it with tools (spreadsheets, tables, drawing files and programs) that provide output that is user friendly, recognizable by the P&ID system, and usable as an interface for a web-based application.

Also, in the middle column and in the middle row, administrators 4077 oversee operation of the overall P&ID system as well as the web application. For example, the administrators 4077 may import one or more templates and associated logic and store them in a location where they can be used in the future by a user 4078 in the web application. In the right column and in the middle row, project designs take place. Specifically, the administrators 4077 import the templates and logic that apply to a particular project for a user 4078. An administrator 4077 may assign one or more people to a project. An administrator may grant certain rights (e.g., view-only access, limited editing ability, administrator rights) to particular people for a project.

The users 4078 (e.g., project managers, project engineers) generate a P&ID design for a project using the P&ID system. For example, a user 4078 may select a number of the various templates (e.g., representing equipment, representing options for a particular piece of equipment, representing subassemblies, representing subsystems) stored in the P&ID system to assemble a P&ID design using the web application. For example, if a user 4078 needs a compressor for part of a crude oil plant, the web application may present multiple options that are available for that design, and the user 4078 may then select from among those options for the P&ID design through the web application.

The P&ID system, through the web application, may then analyze and determine whether the P&ID design is valid (e.g., according to one or more standards, according to one or more protocols). The P&ID system, through the web application, may then provide feedback to the user 4078 with respect to the proposed P&ID design. Such feedback may suggest ways that an invalid P&ID design may be modified to become valid, the cost of purchasing the selected equipment and/or installing the P&ID design, the availability (e.g., lead time) of selected equipment, projected useful life of the selected equipment, projected maintenance costs of the selected equipment, and projected product carbon footprint of a proposed P&ID design. This iterative process may continue until a P&ID design is validated.

A user 4078 for a project may pose different queries and/or present answers to queries on the web application, and the administrator 4077 for that project may present the appropriate templates and associated logic based on the information provided by the user 4078. Included with the users 4078 may be a system that understands the output of the P&ID system and/or the templates and logic of the P&ID system. In such a case, the system of the user 4078 may generate the output (e.g., as spreadsheets, as tables, as single line diagrams) of the P&ID system. In such cases, the system of a user 4078 may perform validation checks on a proposed design. In addition, or in the alternative, the P&ID system (e.g., through the administrators 4077, through the process engineers and developers 4076) may be configured to perform validation checks on the templates and/or logic available on the web application.

In some cases, a user 4078 may input a drawing (e.g., a digital drawing, a hand sketch) into the web application, and the P&ID system (e.g., a controller, an administrator 4077, the process engineers and developers 4076) can evaluate the drawing and potentially incorporate the drawing into a P&ID design. In some cases, a user 4078 selects various templates (e.g., for equipment) from the web application, assembles a design using the templates, and subsequently uploads the design to the web application. In such cases, the web application (e.g., a controller, an administrator 4077, the process engineers and developers 4076) can evaluate the proposed design and provide feedback to the user 4078.

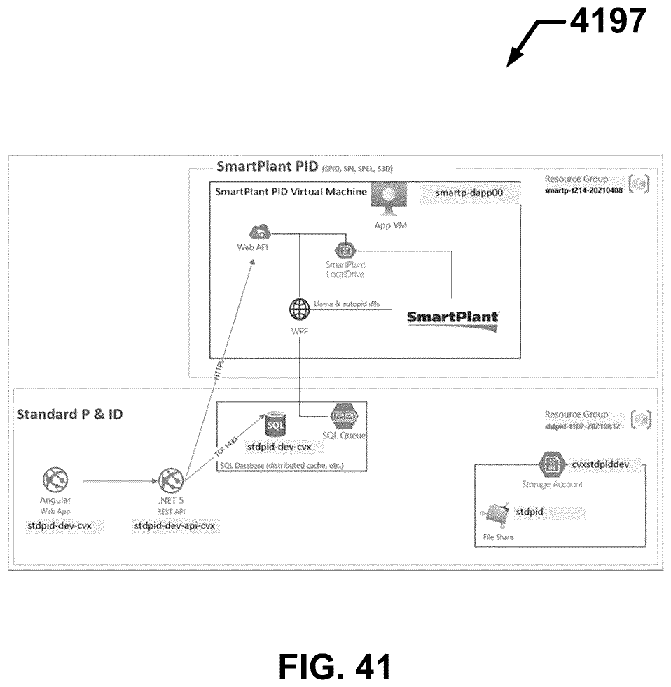

FIG. 41 shows an architecture diagram 4197 of a P&ID system according to certain example embodiments. The architecture diagram 4197 shows the system architecture with an interaction example between a web-based application front end, SQL database, and smart P&ID generation environment. Referring to the description above with respect to FIGS. 1 through 40F, the architecture diagram 4197 organizes the P&ID system into a top tier and a bottom tier. The bottom tier shows the web application (the front end of the P&ID system), behind which is an API, a database (e.g., for storing templates, for storing tables, for storing protocols, for storing industry standards), and user account maintenance. The database may have multiple (e.g., tens, hundreds, thousands) tables for each piece of equipment to detail all of the properties each piece of equipment may have.

The top tier of the architecture diagram 4197 of FIG. 41 shows how the output of the P&ID system may be presented. The output (e.g., drawings of a proposed P&ID system) may be read-only versions. For example, drawings that are output may be viewable and printable, but not editable. In some cases, some or all of the output may be interactive (e.g., using the web application). For example, in such a case, a drawing may be editable by a user. The files output by the P&ID system may be in any suitable format for a user. In some cases, the format of a file output by the P&ID system may be selectable by a user.

Example embodiments can be used to generate a P&ID in real time using a web based application. Example embodiments receive a number of selections of various selection options (or other types of inputs) from a user, and these selections or other types of inputs form the basis of generating subsequent pages and, eventually, one or more P&IDs. Example embodiments are designed to be used in a variety of industries. Using example embodiments, a P&ID can be generated and/or updated in real time to account for changes in available data, user preferences and/or selections, regulations, standards, and/or other sources that can influence changes in how the P&ID is determined. Example embodiments eliminate or greatly reduce the need for human involvement in developing a standard framework with flexibility and customization to determine the P&ID. Example embodiments also provide a number of other benefits. Such other benefits can include, but are not limited to, less use of resources, greater operational flexibility, time savings, standardized processes, reliable P&ID designs, and compliance with applicable industry standards and regulations.

Although embodiments described herein are made with reference to example embodiments, it should be appreciated by those skilled in the art that various modifications are well within the scope and spirit of this disclosure. Those skilled in the art will appreciate that the example embodiments described herein are not limited to any specifically discussed application and that the embodiments described herein are illustrative and not restrictive. From the description of the example embodiments, equivalents of the elements shown therein will suggest themselves to those skilled in the art, and ways of constructing other embodiments using the present disclosure will suggest themselves to practitioners of the art. Therefore, the scope of the example embodiments is not limited herein.

What is claimed is:

1. A method for developing a computer-implemented piping and instrumentation system, the method comprising:
obtaining information about engineering facilities;
obtaining information about equipment used in the engineering facilities;
developing process design logic using the information about the engineering facilities and the equipment;
organizing the information into tables; and
developing templates based on the information and organization of the tables.

2. A computer-implemented method for auto-generating a piping and instrumentation diagram (P&ID) for a corporate entity, the computer-implemented method comprising:
presenting an initial page on a web based application;
obtaining, by the web based application, an input on the page;
validating, by the web based application, the input; and
generating, by the web based application, the P&ID using the input after validating the input.

3. The computer-implemented method of claim 2, further comprising:
organization implementation of the P&ID.

4. A computer-implemented method for auto-generating a piping and instrumentation diagram (P&ID) system, the computer-implemented method comprising:
receiving information about a piece of equipment usable in a P&ID design;
generating a plurality of templates for presenting the information;
organizing the plurality of templates according to protocols that apply to the P&ID design.

5. The computer-implemented method of claim 4, further comprising:
receiving a change in one of the protocols; and
updating the plurality of templates based on the change.
